(19) United States
(12) Patent Application Publication
(10) Pub. No.: US 2022/0373879 A1
(43) Pub. Date: Nov. 24, 2022

(54) THERMAL IMAGING FILM HAVING PARTICULATE-TREATED PROTECTIVE TOPCOAT

(71) Applicant: MIRACLON CORPORATION, Oakdale, MN (US)

(72) Inventor: Kevin Kidnie, St. Paul, MN (US)

(73) Assignee: MIRACLON CORPORATION, Oakdale, MN (US)

(21) Appl. No.: 17/324,695

(22) Filed: May 19, 2021

(51) Int. Cl. G03F 1/48; B41C 1/05; B41N 1/12

(52) U.S. Cl. CPC G03F 1/48; B41C 1/05; B41N 1/12; B41C 2201/02

(57) ABSTRACT

A mask element for flexographic printing can include: a substrate; a polymeric layer on the substrate and having a first infrared absorbing material; a non-silver halide thermally-ablatable imaging layer on the polymeric layer and having a second infrared absorbing material and an ultraviolet absorbing material in an thermally-ablatable polymeric binder; and a particulate-treated protective topcoat on the non-silver halide thermally-ablatable imaging layer and having a thermally-ablatable polymer containing inorganic particles of from about 0.25% to about 20% by dry weight of the particulate-treated protective topcoat. The inorganic particles include silicon dioxide or metal dioxide or combinations thereof. The inorganic particles can be thermally-ablatable particles, such as iron oxide, or be not thermally ablatable particles, such as silica, titanium dioxide, zinc oxide, or combinations thereof. the inorganic particles are present from about 0.5% to 10%. The inorganic particles have a size range from 0.05 microns to 1 micron.

### BACKGROUND

### Field

The present disclosure relates to a thermal imaging film with a particulate treated topcoat protecting layer, and methods of making and using the same. More particularly, the present disclosure relates to a thermal imaging film before or after having a mask element formed therein, wherein the thermal imaging film includes fine inorganic particulates that are optionally non-ablative particles to improve protection and hilite dote retention, and thereby to improve resolution flexographic printing plates.

### Description of Related Art

Previously, photosensitive materials have been combined with masks in flexographic printing plate precursors. However, removal of the mask from the photosensitive relief-forming layer may not be easily performed without damaging the mask or the photosensitive relief-forming layer. Often, the photosensitive relief-forming layer can be damaged during the process of being combined with the mask of being removed from the mask, where the mask may also be damaged. Damaged photosensitive relief-forming layers or mask elements are not useful for flexographic printing plates due to the artifacts or low resolution that result from the damage. As a result, research continues to develop a technology to improve the ability to successfully use a mask with a photosensitive relief-forming layer without causing any damage or losing any resolution.

Photosensitive relief-forming materials having a relief-forming material or photosensitive layer are known in the art. Important advances in the art and useful materials for making flexographic relief images are described in U.S. Patent Application Publication 2005/0227182 (Ali et al., hereinafter cited as U.S. '182). U.S. '182 describes suitable mask element precursors, photosensitive materials for relief-forming layers, and processes and apparatus for forming a mask element from a mask precursor and eventual relief image from a photosensitive relief-forming precursor material.

Typically, a mask element can be placed in intimate contact with a photosensitive relief-forming precursor material using a laminator device or vacuum drawdown, or both, and subjected to overall exposure with actinic radiation (for example, UV radiation) to cure the photosensitive composition in the relief-forming precursor material in the unmasked areas, thus forming a negative image of the mask element in the photosensitive relief-forming precursor. The mask element can then be removed and the uncured regions on the relief-forming material can be removed using a development process. After drying, the resulting imaged relief-forming precursor has a relief image that can be used for flexographic or letterpress printing operations.

Advances in mask element precursors are described in U.S. Pat. No. 7,799,504 (Zwadlo et al.). Other useful mask element precursors and processes for their use are described in U.S. Pat. No. 8,198,012 (Zwadlo et al.), U.S. Pat. No. 8,945,813 (Kidnie), and U.S. Pat. No. 9,250,527 (Kidnie). Advances in photosensitive materials are described in U.S. No. 2019/0258154 (Kidnie). U.S. Pat. No. 8,530,142 (Zwadlo) describes a photopolymer plate precursor which contains a low surface energy release layer over the photosensitive layer to help delamination. U.S. Pat. No. 10,207,491 (Ali et. al.) describes the method of making a flexographic printing plate comprising lamination of a mask image to a flexographic printing plate precursor, UV exposure to form a relief pattern, and delamination of the mask from the photosensitive layer.

While the mask element precursors described in these publications have found considerable value in the flexographic industry, there is a need to further improve the process for making and using the mask elements in an efficient manner and to improve interlayer adhesion, intimate contact of mask element and relief-forming precursor during imaging when a lamination process is used, and a better draw-down of the mask element to the relief-forming precursor when vacuum draw-down is used.

Therefore, there is a need in the art for providing a mask element having the thermal imaging film configured for improved resolution by improving hilite dot retention.

### SUMMARY

In some embodiments, a mask element for flexographic printing can include: a substrate; a polymeric layer on the substrate and having at least one first infrared absorbing material; a non-silver halide thermally-ablatable imaging layer on the polymeric layer and having at least one second infrared absorbing material and an ultraviolet absorbing material in an thermally-ablatable polymeric binder; and a particulate-treated protective topcoat on the non-silver halide thermally-ablatable imaging layer and having a thermally-ablatable polymer containing inorganic particles of from about 0.25% to about 20% by dry weight of the particulate-treated protective topcoat.

In some embodiments, the mask element includes: the polymeric layer including a crosslinked polymer having particles that are not thermally-ablatable; the non-silver halide thermally-ablatable imaging layer including a non-crosslinked polymer; and/or the particulate-treated protective topcoat including a non-crosslinked polymer.

In some embodiments, the mask element includes: the polymeric layer including a non-crosslinked polymer; the non-silver halide thermally-ablatable imaging layer including a non-crosslinked polymer; and the particulate-treated protective topcoat including a non-crosslinked polymer.

In some embodiments, the inorganic particles include silicon dioxide or metal oxide or combinations thereof. In some aspects, the inorganic particles are thermally-ablatable particles, such as iron oxide. In some aspects, the inorganic particles are not thermally ablatable particles, such as silica, titanium dioxide, zinc oxide, or combinations thereof. In some aspects, the inorganic particles are present from about 0.5% to 10%. In some aspects, inorganic particles have a size range from 0.05 microns to 1 micron.

In some embodiments, the mask element includes at least one of: the substrate includes polyethylene terephthalate; the polymeric layer includes polycayanoacrylate; the non-silver halide thermally-ablatable imaging layer includes nitrocellulose; or the particulate-treated protective topcoat includes methacrylic acid-acrylate copolymer.

In some embodiments, the non-silver halide thermally-ablatable imaging layer has a mask image formed therein. The mask image includes regions of the non-silver halide thermally-ablatable imaging layer and regions omitting the non-silver halide thermally-ablatable imaging layer that have been thermally ablated. The particulate-treated protective topcoat includes regions over the regions of the non-silver halide thermally-ablatable imaging layer and omits regions over the regions (e.g., space) omitting the non-silver halide thermally-ablatable imaging layer that have been thermally ablated.

In some embodiments, a relief-forming assembly can include a relief-forming precursor and a mask element for flexographic printing. The mask can include: a substrate; a polymeric layer on the substrate and having at least one first infrared absorbing material; a non-silver halide thermally-ablatable imaging layer on the polymeric layer and having at least one second infrared absorbing material and an ultraviolet absorbing material in an thermally-ablatable ablatable polymeric binder; and a particulate-treated protective topcoat on the non-silver halide thermally-ablatable imaging layer and having a thermally-ablatable polymer containing inorganic particles of from about 0.25% to about 20% by dry weight of the particulate-treated protective topcoat. The non-silver halide thermally-ablatable imaging layer has a mask image formed therein. The mask image includes regions of the non-silver halide thermally-ablatable imaging layer and regions that omit the non-silver halide thermally-ablatable imaging layer that have been thermally ablated. The particulate-treated protective topcoat includes regions over the regions of the non-silver halide thermally-ablatable imaging layer that are present and omits regions over the regions omitting the non-silver halide thermally-ablatable imaging layer (e.g., absent) that have been thermally ablated.

In some embodiments, the relief-forming precursor includes: a substrate; and a relief-forming layer having a bottom surface facing the substrate and a relief-forming surface facing away from the substrate. The relief-forming layer can include: a polymer; at least one photopolymerizable monomer; and a photopolymerization initiator.

In some embodiments, a method of making the relief-forming assembly can include: placing the particulate-treated protective topcoat of the mask element on the relief-forming surface of the relief-forming layer; and forming the complete optical contact between the mask element and the relief-forming surface. In some aspects, the methods can include at least one of: laminating the mask element to the relief-forming surface; or vacuum drawdown coupling the mask element to the relief-forming surface.

In some embodiments, a method of making a relief image in a relief-forming assembly can include: providing the relief-forming assembly of one of the embodiments; exposing a relief-forming layer of the relief-forming precursor to curing UV radiation through the mask element to form an imaged relief-forming layer with UV-exposed regions forming polymerized regions and non-exposed regions forming non-polymerized regions in the imaged relief-forming layer; removing the mask element from the imaged relief-forming layer; and developing the imaged relief-forming layer by removing the non-polymerized regions in the imaged relief-forming layer, thereby forming a relief image element having a relief image.

In some embodiments, a method of making a mask element for flexographic printing can include: providing a substrate; forming a polymeric layer on the substrate, wherein the polymeric layer has at least one first infrared absorbing material; forming a non-silver halide thermally-ablatable imaging layer on the polymeric layer, wherein the non-silver halide thermally-ablatable imaging layer has at least one second infrared absorbing material and an ultraviolet absorbing material in an thermally-ablatable polymeric binder; and forming a particulate-treated protective topcoat on the non-silver halide thermally-ablatable imaging layer, wherein the particulate-treated protective topcoat has a thermally-ablatable polymer containing inorganic particles of from about 0.25% to about 20% by dry weight of the particulate-treated protective topcoat.

In some embodiments, the method of making a mask element for flexographic printing can include: forming the polymeric layer with a crosslinked polymer to form a cross-linked matrix containing particles that are not thermally-ablatable; forming the non-silver halide thermally-ablatable imaging layer to include a non-crosslinked polymer; and forming the particulate-treated protective topcoat to include a non-crosslinked polymer.

In some embodiments, the method of making a mask element for flexographic printing can include: forming the polymeric layer to include a non-crosslinked polymer; forming the non-silver halide thermally-ablatable imaging layer to include a non-crosslinked polymer; and forming the particulate-treated protective topcoat to include a non-crosslinked polymer.

In some embodiments, the method of making a mask element for flexographic printing can include exposing the particulate-treated protective topcoat and non-silver halide thermally-ablatable imaging layer to infrared radiation to selectively ablate regions in the particulate-treated protective topcoat and non-silver halide thermally-ablatable imaging layer. The non-silver halide thermally-ablatable imaging layer has a mask image formed therein, wherein the mask image includes regions of the non-silver halide thermally-ablatable imaging layer and regions omitting the non-silver halide thermally-ablatable imaging layer that have been thermally ablated. The particulate-treated protective topcoat includes regions over the regions of the non-silver halide thermally-ablatable imaging layer and omits regions over the regions omitting the non-silver halide thermally-ablatable imaging layer that have been thermally ablated.

In some aspects, the mask element can include an imaged layer with a mask image. In some aspects, the mask element can be in complete optical contact with the relief-forming surface of the relief-forming layer.

In some embodiments, a method of making a relief-forming assembly can include: providing a mask element in accordance with an embodiment; providing a relief-forming layer that has a low surface energy monomer in accordance with an embodiment; placing an imaged layer of the mask element on a relief-forming surface of the relief-forming layer; and forming the complete optical contact between the mask element and the relief-forming surface. In some aspects, the method can include laminating the mask element to the relief-forming surface. In some aspects, the method can include vacuum drawdown coupling the mask element to the relief-forming surface.

In some embodiments, a method of making a relief image in a relief-forming assembly can include: providing a relief-forming assembly in accordance with an embodiment; exposing the relief-forming layer to curing UV radiation through the mask element to form an imaged relief-forming layer with UV-exposed regions forming polymerized regions and non-exposed regions forming non-polymerized regions in the imaged relief-forming layer; removing the mask element from the imaged relief-forming layer; and developing the imaged relief-forming layer by removing the non-polymerized regions in the imaged relief-forming layer, thereby forming a relief image element having a relief image (e.g., devoid of the non-polymerized regions). In some aspects, the method can include polymerizing the at least one photopolymerizable monomer and optionally a low surface energy monomer with the photopolymerization initiator such that a low surface energy moiety is present in the body and at a relief surface of the relief image of the relief image element.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE FIGURES

The foregoing and following information as well as other features of this disclosure will become more fully apparent from the following description and appended claims, taken in conjunction with the accompanying drawings. Understanding that these drawings depict only several embodiments in accordance with the disclosure and are, therefore, not to be considered limiting of its scope, the disclosure will be described with additional specificity and detail through use of the accompanying drawings.

FIG. 1A is a cross-sectional schematic illustration of an embodiment of a mask precursor according to the present invention, and showing incident infrared radiation useful for making a mask element.

FIG. 1B is a cross-sectional schematic illustration of an embodiment of a mask element formed from the mask precursor illustrated in FIG. 1A.

FIG. 1C is a cross-sectional schematic illustration of an embodiment of a relief image-forming assembly according to the present invention, comprising a mask element as illustrated in FIG. 1B that is in complete optical contact with a relief-forming precursor.

FIG. 1D is a cross-sectional schematic illustration of an embodiment of forming an imaged relief-forming precursor using incident UV radiation through the mask element illustrated in FIG. 1B.

FIG. 1E is a cross-sectional schematic illustration of an embodiment of a relief image element provided after imaging illustrated in FIG. 1D and suitable development process to remove non-exposed regions in the UV-sensitive layer of the imaged relief-forming precursor.

FIG. 2A is a cross-sectional schematic illustration of an embodiment of a mask precursor without particles in a layer according to the present invention, and showing incident infrared radiation useful for making a mask element.

FIG. 2B is a cross-sectional schematic illustration of an embodiment of a mask element formed from the mask precursor illustrated in FIG. 2A.

FIG. 2C is a cross-sectional schematic illustration of an embodiment of a relief image-forming assembly according to the present invention, comprising a mask element as illustrated in FIG. 2B that is in complete optical contact with a relief-forming precursor.

FIG. 2D is a cross-sectional schematic illustration of an embodiment of forming an imaged relief-forming precursor using incident UV radiation through the mask element illustrated in FIG. 2B. The result from FIG. 2D looks identical to as shown in FIG. 1E.

The elements and components in the figures can be arranged in accordance with at least one of the embodiments described herein, and which arrangement may be modified in accordance with the disclosure provided herein by one of ordinary skill in the art.

### DETAILED DESCRIPTION

In the following detailed description, reference is made to the accompanying drawings, which form a part hereof. In the drawings, similar symbols typically identify similar components, unless context dictates otherwise. The illustrative embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein, and illustrated in the figures, can be arranged, substituted, combined, separated, and designed in a wide variety of different configurations, all of which are explicitly contemplated herein.

Mask and Mask Precursor

Generally, the present technology provides an improved thermal imaging film, also referred to as a mask precursor prior to being imaged and a mask subsequent to being imaged. That is, the thermal imaging film (TIF) includes an imaging layer that becomes imaged when exposed to infrared light. The imaging layer can be referred to as the non-silver halide thermally-ablatable imaging layer (IL) because it has no silver halide and it is thermally ablatable by UV. The IL is provided in the mask precursor with a barrier layer (e.g., layer is not thermally ablatable by having crosslinked polymer and non-ablatable particles), and a protective topcoat, with the IL sandwiched therebetween. A substrate can retain the barrier layer thereon, so that the protective topcoat is on top of the IL. The protective topcoat can be treated with small inorganic particulates, e.g., sub-micron range.

A mask with the particulate treated protective topcoat can be configured for use with a relief-forming precursor with the photosensitive layer, where the topcoat comes into contact with the photosensitive layer of the relief-forming precursor. The mask is obtained by imaging a mask precursor with IR light. Thereby, a mask precursor can be prepared and processed with light (e.g., infrared, IR) to form the mask. The mask can then be combined with the relief-forming precursor (e.g., by lamination) and processed with light (e.g., UV), and then the mask and relief-forming precursor that is processed with light are separated from each other. During the separation process, it is important for the relief-forming layer is not damaged or that the protective topcoat is not damaged or does not impart any damage to the relief-forming layer. As such, the particulate-treated protective topcoat can facilitate separation of the mask from the imaged relief-forming layer of the relief-forming precursor. The particulate-treated protective topcoat can inhibit transfer of materials between the mask and relief-forming assembly, such as by inhibiting movement of colorants, light absorbing materials, or other chemical agents from the IL to the relief-forming layer, or vice versa.

The mask precursor can be considered an imageable material due to having an imageable layer that forms the mask. In some embodiments, the mask precursor can include four layers or films as described below, in order: (a) a transparent polymeric carrier sheet (film); (b) a light to heat converting (LTHC) layer or barrier layer; (c) a non-silver halide thermally-ablatable imaging layer (IL); and (d) a particulate-treated protective topcoat. Here, the LTHC layer is non-ablatable by thermal imaging with light, such as IR light. The non-silver halide thermally-ablatable imaging layer is ablatable by thermal imaging with light, such as IR light, but this thermally-ablatable imaging layer does not include a silver halide, and thereby is “a non-silver halide” imaging layer that is thermally ablatable. Accordingly, the LTHC layer includes substances that are not ablatable by thermal energy during imaging the IL layer with IR light. On the other hand, the IL layer includes substances that are thermally ablatable. However, the LTHC layer can be replaced with a barrier layer, such as described herein.

While the protective topcoat is ablatable, it includes particulates that may be ablatable or non-ablatable. While the protective topcoat can include non-ablatable particles, the protective topcoat is still ablatable. In part, the matrix of the protective topcoat can be non-crosslinked polymer so that it is ablatable.

All four layers or films are essential for forming a mask element (e.g., referred to as a mask) having a mask image in the IL layer. The layer (d) particulate-treated protective topcoat, also referred to as a transparent polymeric overcoat layer (e.g., particulate-treated) can be disposed directly on the IL. The particulate-treated protective topcoat can be helpful in some uses for providing abrasion resistance. This can protect the mask element and protect the relief-forming layer. The improvement in abrasion resistance can improve the hilite properties.

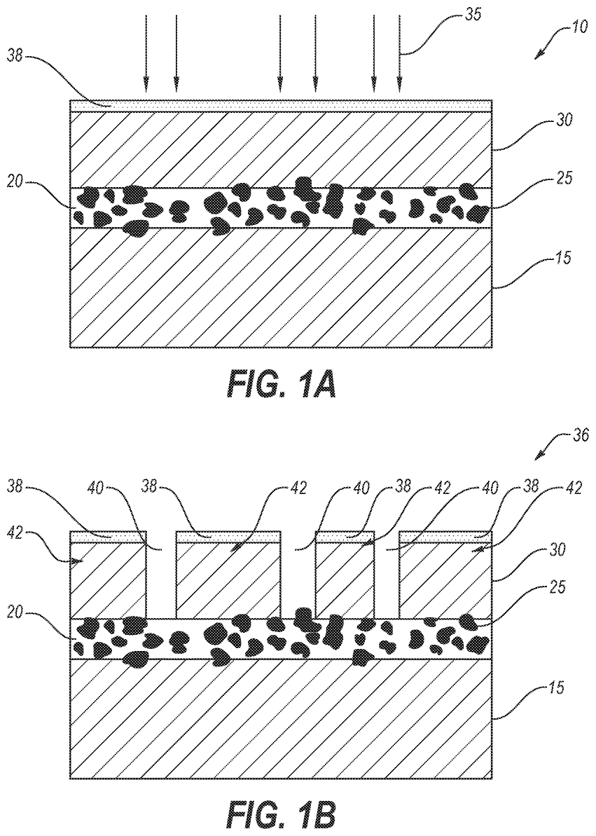

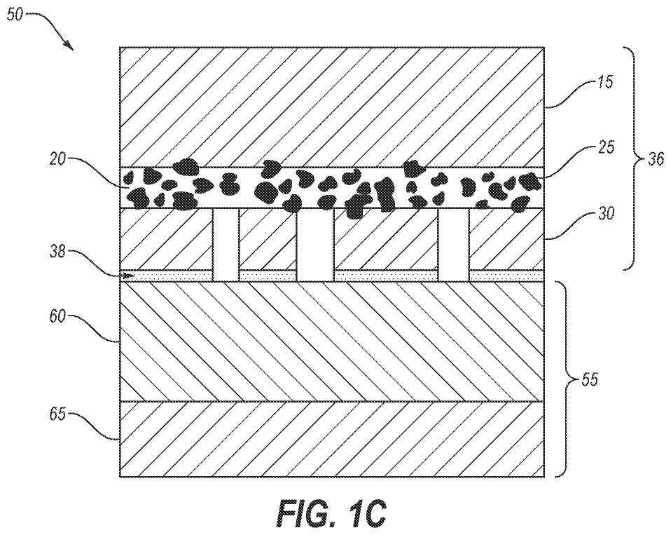

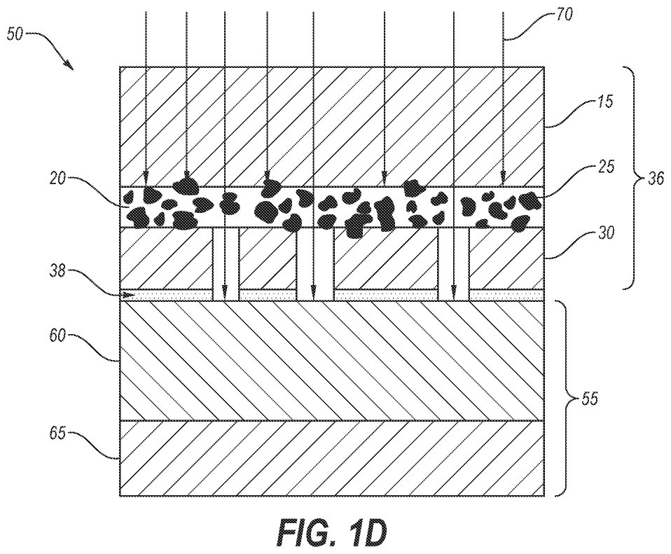

The mask precursor that is used to form a mask element that is used eventually to form a relief image can be prepared and then processed into the mask as described herein. In some embodiments, the mask precursor 10 is illustrated in FIG. 1A, which has (a) transparent polymeric carrier sheet 15, on which is directly disposed (b) LTHC layer 20 containing a non-ablatable binder material having the non-ablatable particles 25 that are described in more detail below, (c) an ablatable IL 30 that is disposed directly on LTHC layer 20 and positioned to receive the light 35 shown by the arrows, and (d) the particulate-treated protective topcoat 38 is provided over the ablatable IL 30.

Transparent Polymeric Carrier Sheet

The transparent polymeric carrier sheet can be any suitable transparent substrate or film. Useful transparent polymeric carrier sheets can be but are not limited to, transparent polymeric films and sheets composed of one or more polymers, such as polyesters including poly(ethylene terephthalate), poly(ethylene naphthalate), and fluorine polyester polymers; polyethylene-polypropylene copolymers; polybutadienes; polycarbonates; polyacrylates (polymers formed at least in part from one or more (meth)acrylate ethylenically unsaturated monomers); vinyl chloride polymers such as polyvinyl chloride and copolymers derived at least in part from vinyl chloride; hydrolyzed or non-hydrolyzed cellulose acetates; and other materials that would be readily apparent to one skilled in the art. The transparent polymeric carrier sheets can be composed of two or more polymeric materials as a blend or composite as long as the requisite transparency and protective properties are achieved. They can be formed as a single polymeric film or laminate of multiple polymeric films. Generally, the transparent polymeric carrier sheet has an average dry thickness of at least 25 μm and up to and including 250 μm, or typically of at least 75 μm and up to and including 175 μm.

For example, a transparent poly(ethylene terephthalate) sheet that is available from various commercial sources is suitable as a transparent polymeric carrier sheet.

If necessary, the transparent polymeric carrier sheet surface can be treated to modify its wettability and adhesion to applied coatings (such as an LTHC layer coating). Such surface treatments include but are not limited to corona discharge treatment and the application of subbing layers as long as the desired transparency (described above) is achieved.

If desired, the transparent polymeric carrier sheet can also comprise one or more “first” ultraviolet radiation absorbing compounds (as described below for the LTHC layer or IL). The one or more compounds of this type can be the same or different as the ultraviolet radiation absorbing compounds in the IL (see below). Each useful ultraviolet radiation absorbing compound generally absorbs electromagnetic radiation of at least 150 nm and up to and including 450 nm. These compounds can be present in the transparent polymeric carrier sheet in an amount of at least 0.01 weight % and up to and including 0.1 weight %, based on the total dry weight of the transparent polymeric carrier sheet.

In addition, the transparent polymeric carrier sheet can contain one or more “adhesion promoters” that improve adhesion between it and the adjacent LTHC layer. Useful adhesion promoters include but are not limited to, gelatin, poly(vinylidene chloride), poly (acrylonitrile-co-vinylidene chloride-co-acrylic acid), and polyethyleneimine.

Non-Ablatable Light-to-Heat Converting (LTHC) Layer

In some embodiments, the mask precursor also includes the non-ablatable LTHC layer disposed on the transparent polymeric carrier sheet and directly between the transparent polymeric carrier sheet and the IL. The LTHC layer can also be swapped with a barrier layer (e.g., see U.S. Pat. No. 9,250,527) in some embodiments as described in more detail below. Suitable LTHC layer compositions have three essential components: a (i) first infrared radiation absorbing material; a (ii) a non-ablatable crosslinked binder material that is a thermally crosslinked organic polymer that is not ablatable by light radiation, such as IR radiation, visible radiation, or UV radiation; and (iii) non-ablatable particles that are not ablatable by light radiation, such as IR radiation, visible radiation, or UV radiation. The LTHC layer is generally disposed as a relatively uniform coating on the transparent polymeric carrier sheet (that is, being substantially continuous and having fairly uniform wet thickness) and then dried if any solvent is present in the composition formulation.

The LTHC layer is generally transparent as that term is defined above. In particular, the LTHC layer is transparent to UV radiation used to image the relief-forming precursor, as defined below.

One or more infrared absorbing materials that are collectively identified herein as the “first” infrared radiation absorbing material to distinguish it, if necessary, from the second infrared radiation absorbing material(s) in the IL (described below). The first infrared radiation absorbing material may also be in the transparent polymeric carrier sheet. The first and second infrared radiation absorbing materials can be one or more dyes or pigments, or mixtures thereof that will provide desired spectral absorption properties and are independently sensitive to electromagnetic radiation in the infrared electromagnetic wavelength range of at least 700 nm and up to and including 1,500 nm and typically of at least 750 nm and up to and including 1,200 nm. Such materials can be particulate in nature and are dispersed within the (ii) non-ablatable crosslinked binder material(s) described below. For example, they can be black dyes or pigments such as carbon black, metal oxides, and other materials described for example in U.S. '182 (noted above).

One suitable IR-absorbing pigment is a carbon black of which there are numerous types with various particles sizes that are commercially available. Examples include RAVEN 450, 760 ULTRA, 890, 1020, 1250 and others that are available from Columbian Chemicals Co. (Atlanta, Ga) as well as BLACK PEARLS 170, BLACK PEARLS 480, VULCAN XC72, BLACK PEARLS 1100 and others available from Cabot Corporation. Other useful carbon blacks are surface-functionalized with solubilizing groups. Carbon blacks that are grafted to hydrophilic, nonionic polymers, such as FX-GE-003 (manufactured by Nippon Shokubai), or which are surface-functionalized with anionic groups, such as CAB-O-JET® 200 or CAB-O-JET® 300 (manufactured by the Cabot Corporation) are also useful.

Useful first infrared radiation absorbing materials also include IR dyes including but not limited to, cationic infrared-absorbing dyes and photothermal-bleachable dyes. Examples of suitable IR dyes include but are not limited to, azo dyes, squarilium dyes, croconate dyes, triarylamine dyes, thiazolium dyes, indolium dyes, oxonol dyes, oxazolium dyes, cyanine dyes, merocyanine dyes, phthalocyanine dyes, indocyanine dyes, indotricarbocyanine dyes, oxatricarbocyanine dyes, thiocyanine dyes, thiatricarbocyanine dyes, merocyanine dyes, cryptocyanine dyes, naphthalocyanine dyes, polyaniline dyes, polypyrrole dyes, polythiophene dyes, chalcogenopyryloarylidene and bi(chalcogenopyrylo) polymethine dyes, oxyindolizine dyes, pyrylium dyes, pyrazoline azo dyes, oxazine dyes, naphthoquinone dyes, anthraquinone dyes, quinoneimine dyes, methine dyes, arylmethine dyes, squarine dyes, oxazole dyes, croconine dyes, porphyrin dyes, and any substituted or ionic form of the preceding dye classes. Suitable dyes are also described in U.S. Pat. No. 5,208,135 (Patel et al.), U.S. Pat. No. 6,569,603 (Furukawa), and U.S. Pat. No. 6,787,281 (Tao et al.), and EP Publication 1,182,033 (Fijimaki et al.). A general description of one class of suitable cyanine dyes is shown by the formula in paragraph [0026] of WO 2004/101280.

Near infrared absorbing cyanine dyes are also useful and are described for example in U.S. Pat. No. 6,309,792 (Hauck et al.), U.S. Pat. No. 6,264,920 (Achilefu et al.), U.S. Pat. No. 6,153,356 (Urano et al.), U.S. Pat. No. 5,496,903 (Watanate et al.), the disclosures of all of which are incorporated herein by reference. Suitable dyes may be formed using conventional methods and starting materials or obtained from various commercial sources including American Dye Source (Baie D′Urfe, Quebec, Canada) and FEW Chemicals (Germany)

The first infrared radiation absorbing material(s) is generally present in an amount sufficient to provide a transmission optical density of at least 0.025 and typically of at least 0.05 at the exposing electromagnetic radiation wavelength (e.g., IR). Generally, this is achieved by including at least 0.1 weight % and up to and including 5 weight %, or typically at least 0.3 weight % and up to and including 3 weight %, based on the total dry weight of the LTHC layer.

The first infrared radiation absorbing material in the LTHC layer can be the same or different chemical material(s) as the second infrared radiation absorbing compound that is incorporated into the IL as described below. The infrared radiation absorbing material in the LTHC layer may also be different from the infrared radiation absorbing material in the transparent polymeric carrier. In most embodiments, the first and second infrared radiation absorbing materials are the same chemical materials. The amounts of the first and second infrared radiation absorbing materials in the imageable material can be the same or different. In most embodiments, they are present in different amounts in the imageable material.

As noted, the LTHC layer comprises a non-ablatable crosslinked binder formed from one or more thermally crosslinked organic polymeric binders derived from thermally crosslinkable organic polymeric binders that have been crosslinked. The term “thermally crosslinkable” means that crosslinking groups are present and include for example, hydroxy-containing polymers. Particularly useful thermally crosslinkable organic polymers include but are not limited to, crosslinkable nitrocellulose; crosslinkable polyesters such as polyesters containing hydroxy groups; polyvinyl alcohol's; polyvinyl acetals such as polyvinyl butyral; or a combination of two or more of such crosslinkable organic polymeric materials. The corresponding non-ablatable crosslinked binder material can be obtained by crosslinking the noted thermally crosslinkable organic polymeric materials.

The non-ablatable crosslinked binder material formed from thermally crosslinked organic polymers can be present in the LTHC layer in an amount of at least 40 weight % and up to and including 90 weight %, or more likely in an amount of at least 50 weight % and up to and including 80 weight %, all based on total dry weight of the LTHC layer.

A third essential component of the LTHC layer are the non-ablatable particles, which are not ablatable by light radiation or resulting thermal heat from light radiation, and thereby the non-ablatable particles are considered to be non-thermally-ablatable particles. The non-thermally-ablatable particles are defined to be not thermally ablative under exposure to the light radiation during formation of the mask or formation of the relief image. The non-ablatable particles can include an average particle size of at least 0.1 μm and up to and including 20 μm, or at least 5 μm and up to and including 15 μm. The term “average” is used here to refer to measurements of particle size of the dispersed particles and can be determined from either a manufacturer's specification or by measuring at least 10 different particles and taking an average.

The term “non-ablatable” with regard to the non-ablatable particles is used here to mean that the particles are not sensitive to the laser imaging wavelength and intensity compared to materials that are strongly affected by the laser imaging ablation process of forming the mask. Also, the particles are not sensitive to UV radiation during formation of the relief image from the mask and the relief-forming precursor. Materials that are sensitive to the laser thermal imaging ablation process have strong absorption to the laser wavelength of the imaging laser and have low thermal decomposition temperatures so that they are ablative, and such materials are not used in the non-ablatable particles. Conversely, non-ablative particles used in the present invention are not strongly absorbing of the laser imaging wavelength and do not have very low thermal decomposition temperatures. Some of the non-thermally-ablatable particles can protrude out of the LTHC layer, for example, into the IL, but are retained in the LTHC layer or at least partially embedded therein.

The non-ablatable particles useful in the LTHC layer include but are not limited to, particles of silica, titanium dioxide, zinc oxide, or a combination of two or more types of such particles. Silica particles are particularly useful in the practice of this invention. Moreover, such non-ablatable particles can be present in the LTHC layer in an amount of at least 0.2 weight % and up to and including 10 weight %, or at least 1 weight % and up to and including 7 weight %, all based on the total dry weight of the LTHC layer.

Optionally, during formation the LTHC layer can comprise one or more thermal crosslinking agents to provide improved handling of the mask element. Such optional thermal crosslinking agents facilitate crosslinking of the thermally crosslinkable organic binder polymers during coating and drying of the LTHC layer to form the non-ablatable crosslinked binder. Heat can be used for drying during formation of the mask element. The thermal crosslinking agent(s) can be present in an amount of at least 5 weight % and up to and including 25 weight %, based on the total dry weight of the crosslinkable polymer that is crosslinked into the non-ablatable LTHC layer. Such materials can include but are not limited to, melamine-formaldehyde resins, dialdehydes, phenolics, polyfunctional aziridines, isocyanates including polyisocyanates, and urea-formaldehyde epoxies. However, the formed LTHC layer is a crosslinked binder so crosslinking agents can be all used or not present or only present in small amounts in the formed crosslinked material that is non-ablative.

The LTHC layer generally has an average dry thickness of at least 1 μm and up to and including 5 μm or typically at least 1 μm and up to and including 3 μm.

Non-Silver Halide Thermally-Ablatable Imaging Layer (IL)

The IL that is incorporated into the mask precursor is generally disposed directly on the LTHC layer as a relatively uniform coating (that is, being substantially continuous and having fairly uniform wet thickness) and then dried if any solvent is present in the formulation. In most embodiments, IL is a single coated or applied layer, but in other embodiments, there can be multiple sub-layers or sub-coatings making up the IL disposed directly on the LTHC layer described above.

As stated in the terminology, there is essentially no silver halide present in the IL. In other words, no silver halide is purposely added or created in the IL.

The IL generally includes one or more ultraviolet radiation absorbing materials (UV-light absorbing materials) as a component. These compounds generally have an absorbance of at least 1.5 and up to and including 5 in an electromagnetic radiation wavelength range of at least 300 nm and up to and including 450 nm. In general, useful ultraviolet radiation absorbing materials include but are not limited to benzotriazoles, halogenated benzotriazoles, triazines, benzophenones, benzoates, salicylates, substituted acrylonitriles, cyanoacrylates, benzilidene malonates, oxalanilides, and mixtures thereof. Examples of useful ultraviolet radiation absorbing materials include but are not limited to, UV absorbing dyes or UV stabilizers marketed under the names Uvinul® (BASF), Keyplast® (Keystone Aniline Corporation), Sanduvor® (Sandoz Chemicals Corp.), Hostavin (Clariant), and Tinuvin® (BASF or Ciba). Examples of useful materials are described in U.S. Pat. No. 5,496,685 (Farber et al.).

The one or more ultraviolet radiation absorbing compounds can be present in the IL in an amount of at least 10 weight % and up to and including 40 weight %, or typically at least 15 weight % and up to and including 30 weight %, based on the total dry weight of the IL.

The IL also comprises one or more second infrared radiation absorbing materials as a second essential component, which second infrared radiation absorbing materials are defined like the first infrared radiation absorbing materials described above for the LTHC layer, and they can be the same or different as the first infrared radiation absorbing materials. The one or more second infrared radiation absorbing materials can be present in the IL in an amount sufficient to provide a transmission optical density of at least 0.5 and typically of at least 0.75 at the exposing wavelength. Generally, this is achieved by including at least 3 weight % and up to and including 20 weight % of the one or more second infrared radiation sensitive compounds, based on the total dry weight of the IL.

The IL can optionally include one or more fluorocarbon additives for improved production of halftone dots (that is, pixels) having well-defined, generally continuous, and relatively sharp edges. Examples of useful fluorocarbon additives and amounts are provided in [0087] to [0089] of U.S. '182 (noted above).

Additional optional components of the IL include but are not limited to, plasticizers, coating aids or surfactants, dispersing aids, fillers, and colorants, all of which are well known in the art as described for example in [0094] to [0096] of U.S. '182 (noted above). For example, the IL further can comprise one or more fluorocarbon additives or one or more non-thermally ablatable colorants.

All the essential and optional components described above for the IL are dispersed in one or more ablatable polymeric binder materials that include both synthetic and naturally occurring polymeric materials that are ablatable when exposed to light radiation, such as such as IR radiation, visible radiation, or UV radiation. In some aspects, the ablatable polymeric binder in the IL is not crosslinked, and thereby is a non-crosslinked binder. Such materials are capable of dissolving or dispersing the essential and optional components in a uniform manner throughout the IL. The one or more ablatable polymeric binder materials can be present in an amount of at least 25 weight % and up to and including 75 weight %, or typically of at least 35 weight % and up to and including 65 weight %, based on the total dry weight of the IL.

Useful ablatable polymeric binder materials include but are not limited to, the materials described for example in [0081] to [0085] of US '182. These materials can also be known as “adhesive binders” as described for example in [0081] of U.S. '182. Examples of such materials include but are not limited to, acetyl polymers such as poly(vinyl butyral)s that can be obtained for example as BUTVAR® B-76 from Solution, Inc. (St. Louis, Mo.) and acrylamide polymers that can be obtained as MACROMELT 6900 from Henkel Corp. (Gulph Mills, Pa.). Pressure-sensitive adhesive polymers can also be used for this purpose.

In some embodiments, it is advantageous to use binder materials in the IL that are easily thermally-combustible or thermally-ablatable, and that generate gases and volatile fragments at temperature less than 200° C. Examples of these materials are thermally ablatable nitrocellulose, polycarbonates, poly(cyanoacrylate)s, polyurethanes, polyesters, polyorthoesters, polyacetals, and copolymers thereof (see for example, U.S. Pat. No. 5,171,650 of Ellis et al., Col. 9, lines 41-50, the disclosure of which is incorporated herein by reference), which can be non-crosslinked.

Other useful ablatable materials for the IL have hydroxyl groups (or hydroxylic polymers) as described in [0082] to [0084] of U.S. '182 (noted above) such as poly(vinyl alcohol)s and cellulosic polymers (such as nitrocellulose). Still other useful polymers are non-crosslinkable polyesters, polyamides, polycarbamates, polyolefins, polystyrenes, polyethers, polyvinyl ethers, polyvinyl esters, and polyacrylates and polymethacrylates having alkyl groups with 1 and 2 carbon atoms.

Particularly useful abatable materials for the IL include but are not limited to, a polyurethane, poly(vinyl butyral), (meth)acrylamide polymer, nitrocellulose, polyacetal, poly(cyanoacrylate), a polymer derived at least in part from any of methyl methacrylate, ethyl methacrylate, n-butyl methacrylate, and isobutyl methacrylate, or a combination of two or more of these materials.

The IL can have an average dry thickness of at least 0.5 pm and up to and including 5 μm or typically of at least 0.8 μm and up to and including 2.5 μm.

Particulate-Treated Protective Topcoat

The mask precursor includes a transparent polymeric overcoat layer that is disposed directly on the IL opposite of the LTHC layer. This transparent polymeric overcoat layer can be referred to as a particulate-treated protective topcoat. The addition of particulates into such a particulate-treated protective topcoat provides the advantages of improved resolution and increased hilite dot retention for the present invention. The particulate-treated protective topcoat generally includes one or more transparent film-forming polymers or resins including but not limited to, a methacrylic acid copolymer (such as a copolymer of ethyl methacrylate and methacrylic acid). The body of the particulate-treated protective topcoat can include the small particles as described herein. The particles can be inorganic particles, which can be silica or metal oxide particles, of less than 1 micron in size. The metal oxide particles can be ablative, such as iron oxide particles. Alternatively, the metal oxide particles can be non-ablative, such as titanium dioxide, or zinc oxide. Non-ablative silica particles may also be used. These inorganic particles can be from 0.001 microns to about 0.99 microns, or about 0.01 microns to about 0.75 microns, or about 0.05 microns to about 0.5 microns, or from about 0.1 microns to about 0.25 microns, or any range between any of the recited values.

The inorganic particles may be non-ablative particles as described herein. However, the particulate-treated protective topcoat is ablatable, and thereby the polymeric body is not cross-linked. The body can be prepared to be ablatable, which may be similar to the body composition of the IL.

The particulate-treated protective topcoat can provide abrasion resistance during handling due to the presence of the inorganic particles and fluoropolymer particulates. It can also act as a barrier to prevent chemical migration from the mask element to the relief-forming precursor when they are in complete optical contact. Also, the inorganic particles can improve the resolution and hilite dot retention.

The particulate-treated protective topcoat can be attached directly to the IL and can have an average dry thickness of at least 0.05 μm and up to and including 1 μm. The thickness may be varied depending on the size of the inorganic particles.

In some embodiments, it is advantageous to use binder materials in the particulate-treated protective topcoat that are easily thermally-combustible or thermally-ablatable, and that generate gases and volatile fragments at temperature less than 200° C. Examples of these materials are thermally ablatable nitrocellulose, polycarbonates, poly(cyanoacrylate)s, poly(methacrylates), poly(ethyl acrylates), polyurethanes, polyesters, polyorthoesters, polyacetals, and copolymers thereof (see for example, U.S. Pat. No. 5,171,650 of Ellis et al., Col. 9, lines 41-50, the disclosure of which is incorporated herein by reference), which can be non-crosslinked. A 1:1 methacrylic aid-ethyl acrylate copolymer, such as Kolicoat® MAE30 DP is an example.

Other useful ablatable materials for the particulate-treated protective topcoat have hydroxyl groups (or hydroxylic polymers) as described in [0082] to [0084] of U.S. '182 (noted above) such as poly(vinyl alcohol)s and cellulosic polymers (such as nitrocellulose). An example grouping of useful polymers are non-crosslinkable polyesters, polyamides, polycarbamates, polyolefins, polystyrenes, polyethers, polyvinyl ethers, polyvinyl esters, and polyacrylates and polymethacrylates having alkyl groups with 1 and 2 carbon atoms, and copolymers thereof. Particularly useful abatable materials for the particulate-treated protective topcoat include but are not limited to, a polyurethane, poly(vinyl butyral), (meth)acrylamide polymer, nitrocellulose, polyacetal, poly(cyanoacrylate), a polymer derived at least in part from any of methyl methacrylate, ethyl methacrylate, n-butyl methacrylate, and isobutyl methacrylate, or a combination of two or more of these materials, such as a copolymer.

The non-ablatable particles useful in the particulate-treated protective topcoat include but are not limited to, particles of silica, titanium dioxide, zinc oxide, or a combination of two or more types of such particles. Silica particles are particularly useful in the practice of this invention. Moreover, such non-ablatable particles can be present in the particulate-treated protective topcoat in an amount of at least 0.1 weight % and up to and including 20 weight %, or at least 0.5 weight % and up to and including 17 weight %, or at least 0.75 weight % and up to and including 15 weight %, or at least 1 weight % and up to and including 12 weight %, or at least 1.25 weight % and up to and including 10 weight %, or at least 1.5 weight % and up to and including 7 weight %, or any range between any of the recited values, such as 1-7%. All percentages based on the total dry weight (e.g., without water) of the particulate-treated protective topcoat layer.

In addition to the inorganic particles, the particulate-treated protective topcoat can include fluoro-particles of one or more fluoropolymers dispersed therein as described, for example, in U.S. Pat. No. 6,259,465 (Tutt et al.) the disclosure of which is incorporated herein by reference. An example can include polytetrafluorethylene (PTFE). The fluoro-particles can be present in an amount significantly less than the inorganic particles, where the amount can be less than 0.18% or less than 0.018%. All percentages based on the total dry weight (e.g., without water) of the particulate-treated protective topcoat layer.

Additionally, the particulate-treated protective topcoat can include a surfactant, such as a fluoro-surfactant. The fluoro-surfactant can be Capstone FS-3100. The fluoro-surfactant can be present in an amount significantly less than the fluro-particles, where the amount can be less than 0.01% or less than 0.001%. All percentages based on the total dry weight (e.g., without water) of the particulate-treated protective topcoat layer.

In some embodiments, a silicone-containing surface additive can be included in the particulate-treated protective topcoat. The silicone-containing surface additive can be a polyether modified polydimethylsiloxane, such as BYK 333. The silicone can be present in an amount significantly less than the fluro-surfactant, where the amount can be less than 0.007% or less than 0.0007%. All percentages based on the total dry weight (e.g., without water) of the particulate-treated protective topcoat layer.

Mask with Barrier Layer

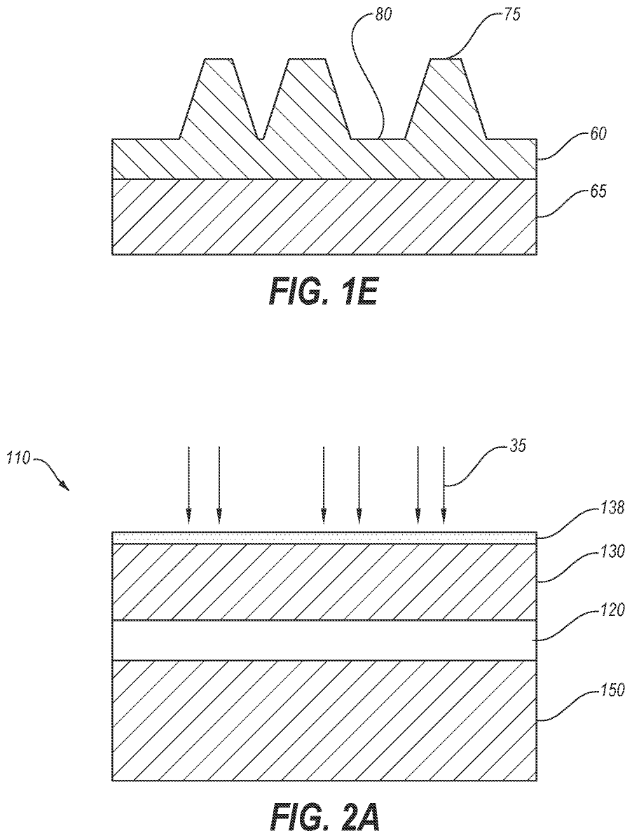

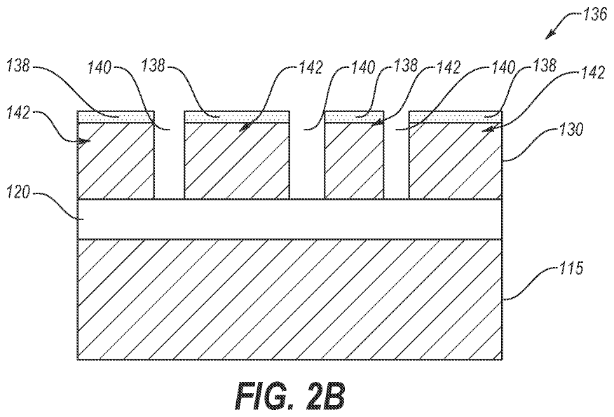

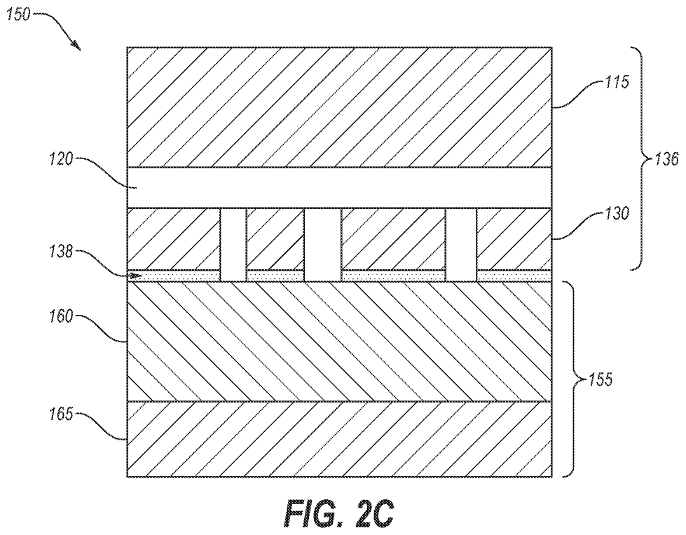

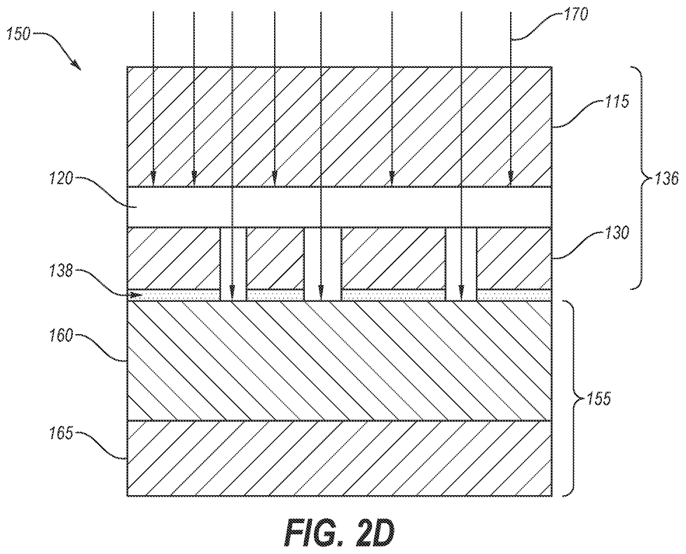

The mask precursor can be considered an imageable material due to having an imageable layer that forms the mask. In some embodiments, the mask precursor can include four layers or films as described below and shown in FIG. 2A, in order: (a) a transparent polymeric carrier sheet (film) optionally having a first ultraviolet absorbing compound; (b) a barrier layer having a first infrared radiation absorbing compound optionally having a first ultraviolet absorbing compound (e.g., one of (a) or (b) has the first ultraviolet absorbing compound); (c) a non-silver halide thermally-ablatable imaging layer (IL) having a second infrared radiation absorbing compound and second ultraviolet absorbing compound; and (d) a particulate-treated protective topcoat. Here, the barrier layer is non-ablatable by thermal imaging with light, such as IR light, but omits any non-ablatable particles. The non-silver halide thermally-ablatable imaging layer is ablatable by thermal imaging with light, such as IR light, but this thermally-ablatable imaging layer does not include a silver halide, and thereby is “a non-silver halide” imaging layer that is thermally ablatable. Accordingly, the barrier layer includes substances that are not ablatable by thermal energy during imaging the IL layer with IR light. On the other hand, the IL layer includes substances that are thermally ablatable. While the protective topcoat is ablatable, it includes particulates that may be ablatable or non-ablatable. While the protective topcoat can include non-ablatable particles, the protective topcoat is still ablatable due to the polymer matrix being non-crosslinked.

The mask precursor that is used to form a mask element that is used eventually to form a relief image can be prepared and then processed into the mask as described herein. In some embodiments, the mask precursor 110 is illustrated in FIG. 2A, which has (a) transparent polymeric carrier sheet 115, on which is directly disposed (b) barrier layer 120 containing an ablatable binder material, (c) an ablatable IL 130 that is disposed directly on barrier layer 120 and positioned to receive the light 35 shown by the arrows 35, and (d) the particulate-treated protective topcoat 138 is provided over the ablatable IL 130. The mask precursor 110 can be used substantially as described in connection to the mask precursor 10 embodiment. Therefore, embodiments, with mask precursor 10 can be replaced with mask precursor 110.

The exposing step is illustrated for some embodiments in FIG. 2A in which the mask precursor material 110 is exposed to exposing infrared radiation 35 in an imagewise pattern to provide exposed regions 140 and non-exposed regions 142 as illustrated in mask element shown in FIG. 2B and corresponding to a mask image. As shown, the exposed regions 140 are ablated and are removed from the non-exposed regions 142. As such, the exposed regions 140 form the mask image.

Some embodiments according to the present invention can be understood by reference to the general illustrations provided in the sequence of FIG. 2A through FIG. 2D. As described above, FIG. 2A illustrates mask precursor 110 that is exposed to exposing infrared radiation 35 to form mask element (FIG. 2B).

In FIG. 2C, the mask element 136 includes the IL layer 115 over the barrier layer 120 that is over the ablated IL layer 130 that has the mask image formed therein with the ablated particulate-treated protective topcoat 138). The mask element 136 is shown in intimate or complete optical contact with a relief-forming precursor 155 to provide relief-image forming assembly 150 by contacting the particulate-treated protective topcoat 138. Relief-forming precursor 155 includes the UV-sensitive layer 160 that is typically carried on substrate 165.

FIG. 2D shows the step of exposing the relief-image forming assembly 150 to UV radiation 170 shown by the arrows. The UV radiation 170 passes through the transparent polymeric carrier sheet 115, the barrier layer 120, and the exposed regions (e.g., element 140—removed IL layer portions) of IL 130 in the mask element 136 and then the exposed portions in the particulate-treated protective topcoat 138 to cause photocuring in UV-sensitive layer 160 of the relief-forming precursor 155.

After the UV-exposure, mask element 136 can be removed from the UV-sensitive layer 160 of the relief-forming precursor 155 and a development protocol can provide a relief image (same result as shown in FIG. 1E) in the UV-sensitive layer 160. As shown in FIG. 1E, the relief image includes relief image peaks 75 and relief image valleys 80 in the UV-sensitive layer 60.

It is noted that the particulate-treated protective topcoat 138 is peeled from the UV-sensitive layer 160. The particulates can improve the resolution and hilite retention of the resulting relief image shown in FIG. 1E.

In some embodiments, the barrier layer is carried out using an imageable material of the present invention that is defined with the following features: (a) the first ultraviolet radiation absorbing compound is present only in the barrier layer, the first and second ultraviolet radiation absorbing compounds in the imageable material are the same or different UV-absorbing dyes, and the amount of the first ultraviolet radiation absorbing compound is less than the amount of the second ultraviolet radiation absorbing compound, or (b) the barrier layer in the imageable material comprises a heat-combustible polymer binder that is nitrocellulose, a poly(cyanoacrylate), or a combination thereof, and optionally metal oxide particles or crosslinking agents or the barrier layer is a metal or metalized layer.

In some embodiments, the IL in the imageable material comprises a polymer or resin binder that is a polyurethane, poly(vinyl butyral), (meth)acrylamide polymer, nitrocellulose, polyacetal, polymer derived at least in part from any of methyl methacrylate, ethyl methacrylate, n-butyl methacrylate, and isobutyl methacrylate, or a combination of two or more of these materials.

In some embodiments, the transparent polymeric carrier sheet comprises a polyester, polyethylene-polypropylene copolymer, polybutadiene, polycarbonate, polyacrylate, vinyl chloride polymer, hydrolyzed or non-hydrolyzed cellulose acetate, or a combination of two or more of these materials, and optionally comprising an adhesion promoter.

If desired, the transparent polymeric carrier sheet can also comprise one or more “first” ultraviolet radiation absorbing compounds (as described below for the barrier layer). The one or more compounds can be the same or different as the first ultraviolet radiation absorbing compound in the barrier layer, and they can be the same or different compounds as the “second” ultraviolet radiation absorbing compounds as described below. Each of these ultraviolet radiation absorbing compounds generally absorbs radiation of at least 150 nm and up to and including 450 nm. These compounds can be present in the transparent polymeric carrier sheet in an amount of at least 0.01 weight % and up to and including 0.1 weight %, based on the total dry transparent polymeric carrier sheet weight.

In addition, the transparent polymeric carrier sheet can contain one or more “adhesion promoters” that improve adhesion between it and the adjacent barrier layer. Useful adhesion promoters include but are not limited to, gelatin, poly(vinylidene chloride), poly(acrylonitrile-co-vinylidene chloride-co-acrylic acid), and polyethylenimine

The imageable material of this invention also comprises a barrier layer disposed directly between the transparent polymeric carried sheet and the IL. Suitable barrier compositions are also described in US '182 (noted above) and references cited therein. For example, the barrier layer can comprise one or more polymer binders, particularly, “heat-combustible” polymer binders (e.g., not crosslinked) such as poly(alkyl cyanoacrylate)s and nitrocellulose, or a combination thereof, or particulate materials such as metal oxide particles (for example, iron oxide particles) to provide high optical density with respect to relief-image forming curing radiation. Metal oxide particles can be useful for ablative imaging because they can thermally decompose to generate propulsive gases. When the barrier layer comprises one or more polymer binders, those materials are present in an amount of at least 50 weight % and up to and including 99 weight %, based on total dry barrier layer weight.

The barrier layer can alternatively be composed of a metal or metalized layer in place or part or all of the polymer binders.

The barrier layer further comprises one or more infrared absorbing compounds that are collectively identified herein as the “first” infrared radiation absorbing compound to distinguish it, if necessary, from the second infrared radiation absorbing compound in the IL. The first infrared radiation absorbing compound can be one or more dyes or pigments, or mixtures thereof that will provide desired spectral absorption properties and is sensitive to radiation in the range of at least 700 nm and up to and including 1500 nm and typically at least 750 nm and up to and including 1200 nm. It can be a particulate material that is dispersed within the polymeric binder(s) described below. For example, they can be black dyes or pigments such as carbon black, metal oxides, and other materials described for example in US '182 (noted above). The same infrared radiation absorbing materials described herein can be used in the barrier layer.

The infrared radiation absorbing compound is generally present in the barrier layer in an amount to provide a transmission optical density of at least 0.025 and typically of at least 0.05 at the exposing wavelength. Generally, this is achieved by including at least 0.2 weight % and up to and including 2 weight %, or typically at least 0.3 weight % and up to and including 1 weight % of the one or more infrared radiation absorbing compounds, based on the total dry weight of the barrier layer.

The first infrared radiation absorbing compound in the barrier layer can be the same or different chemical compound(s) as the second infrared radiation absorbing compound that is incorporated into the non-silver halide thermally sensitive imageable layer that is described below. In most embodiments, the first and second infrared radiation absorbing compounds are the same chemical materials. The amounts of the first and second infrared radiation absorbing compounds in the imageable material can be the same or different. In most embodiments, they are present in different amounts in the imageable material.

In addition, in addition to or alternatively to the transparent polymeric carrier sheet, the barrier layer can comprise one or more ultraviolet radiation absorbing compounds that are collectively identified herein as the “first” ultraviolet radiation absorbing compound to distinguish it, if necessary, from the second ultraviolet radiation absorbing compound in the non-silver halide thermally sensitive imageable layer. These compounds generally absorb radiation of at least 150 nm and up to and including 450 nm. In most embodiments, the first ultraviolet radiation absorbing compounds are provided only in the barrier layer. In general, useful ultraviolet radiation absorbing compounds are described herein.

Optionally, the barrier layer can be devoid of a crosslinking agent or devoid of crosslinked polymers.

The barrier layer generally has an average dry thickness of at least 0.25 μm and up to and including 2.5 μm or typically at least 0.5 μm and up to and including 1.5 μm. The average dry thickness is measured in a manner similar to that for the non-silver halide thermally sensitive layer described below.

The particles in the particulate-treated protective topcoat can be ablative particles that are ablated by IR light or non-ablative particles that are not ablated by IR light. The ablative particles can be iron oxide. The non-ablative particles can be silica (e.g., silicon dioxide), titanium dioxide, zinc oxide, or combinations thereof. Combinations of ablative and non-ablative particles can also be used in the particulate-treated protective topcoat.

Forming Mask Elements

In some embodiments, a mask can be formed by producing exposed and non-exposed regions in the IL of the mask precursor embodiments described herein (e.g., with the barrier layer or LTHC layer. The choice of imaging mechanism will determine the possible variations in forming the mask image, as described below.

Exposing the mask precursor to ablative light energy to ablate the IL layer and protective topcoat can be carried out in selected regions, otherwise known as “imagewise exposure.” In some embodiments, imagewise exposure can be accomplished using thermal radiation from a thermal or infrared laser that is scanned or rasterized under computer control. Any of the known scanning devices can be used including flat-bed scanners, external drum scanners, and internal drum scanners. In these devices, the mask precursor material is secured to the drum or bed, and the laser beam is focused to a spot that can impinge on the IL of the mask precursor material. Two or more lasers can scan different regions of the IL simultaneously.

For example, the mask precursor material can be exposed to infrared radiation, for example, in the electromagnetic wavelength range of at least 700 and up to and including 1500 nm. Such mask precursor materials contain one or more second infrared radiation absorbing materials in the IL as described above to provide sensitivity to infrared radiation. In these embodiments, the mask precursor material can be suitably mounted to an infrared imager and exposed to the infrared radiation using an infrared laser such as a diode laser or Nd:YAG laser that can be scanned under computer control. Suitable infrared imagers include but are not limited to TRENDSETTER imagesetters and ThermoFlex Flexographic CTP imagers available from Eastman Kodak Company used for CTP lithographic plate applications and for imaging flexographic elements, DIMENSION imagesetters available from Presstek (Hudson, N.H.) useful for CTP lithographic plate applications, CYREL® Digital Imager (CDI SPARK) available from Esko-Graphics (Kennesaw, Ga.), and OMNISETTER imagers available from Misomex International (Hudson, N.H.) useful for imaging flexographic elements.

This exposing step is illustrated for some embodiments in FIG. 1A in which mask precursor material 10 is exposed to exposing infrared radiation 35 in an imagewise pattern to provide exposed regions 40 and non-exposed regions 42 as illustrated in mask element 36 shown in FIG. 1B and corresponding to a mask image. As shown, the exposed regions 40 are ablated and are removed from the non-exposed regions 42. As such, the exposed regions form the mask image. The same protocol can be performed with mask precursor material 110 of FIG. 2.

The step of forming the mask image can also include a step of removing either exposed or non-exposed regions from the IL if desired. In some embodiments, exposed regions of the IL are removed for example by ablating away the exposed material(s) in the IL. In this mechanism, the exposed regions of the IL are removed from the mask element by the generation of a gas during ablation to leave a mask image. Specific binders (e.g., non-crosslinked) that decompose upon exposure to heat (such as that produced by IR laser irradiation) to rapidly generate a gas can be present in the IL. This action is to be distinguished from other mass transfer techniques in that a chemical rather than a physical change causes an almost complete transfer of the IL rather than a partial transfer.

In other embodiments not illustrated, a mask image can be formed on the carrier sheet by producing exposed and non-exposed regions in the IL and selectively removing the non-exposed regions.

In some embodiments, the mask image in the IL of the mask element can be cured by subjecting it to heat treatment, provided that the properties of the mask element are not adversely affected. Heat treatment can be carried out by a variety of means including but not limited to, storage in an oven, hot air treatment, or contact with a heated platen or passage through a heated roller device. Heat treatment is not necessary for curing to take place.

In still other embodiments, a mask image can be formed in the IL as noted above and the exposed regions can be transferred to a receptor sheet that is then removed from the mask element before it is brought into contact with to a relief-forming precursor. Such procedures are well known in the art.

In a peel-apart imaging mechanism, the exposed regions of the IL can be removed from the carrier sheet using a suitable receptor sheet based on differential adhesion properties in the IL. After imagewise exposure of the mask precursor, the receptor sheet is separated from the carrier sheet and either exposed or non-exposed regions remain in the mask element.

Relief-Forming Precursor

In some embodiments, a photosensitive relief-forming material can be used in a relief-forming photopolymer plate precursor. The photosensitive relief-forming layer can be processed to form a relief image. The photosensitive relief-forming layer can also be used in solvent wash plates or water wash plates.

Considerable details of useful relief-forming precursors, such as flexographic printing plate precursors, letterpress printing plate precursors, and printed circuit boards are provided in U.S. '182 (noted above). Such relief-forming precursors can include a suitable dimensionally stable substrate and a relief-forming layer that is UV (ultraviolet)-sensitive, and optionally a coversheet and/or metal layer between substrate and relief-forming layer. Suitable substrates include dimensionally stable polymeric films and aluminum sheets. Polyester films are particularly useful. Any UV-sensitive material or element in which a relief image can be produced using a mask element is useful in the practice of this invention when it includes a low surface energy additive.

In some embodiments, relief-forming precursors generally include a suitable dimensionally stable substrate, a radiation curable layer in which a flexographic relief image can be formed, and optionally a cover sheet on the radiation curable layer and/or metal layer between the substrate and radiation curable layer. Suitable substrates include flexible, dimensionally stable transparent polymeric films as well metal substrates, such as aluminum sheets. Polyester films are particularly useful as flexible, dimensionally stable, transparent substrates. The relief-forming precursor can optionally include a metal layer disposed between the substrate and the radiation curable layer. This metal layer can include copper or another metal or metal alloy.

Some embodiments also include a removable coversheet that protects the radiation curable layer from fingerprints and other damage and that is disposed on the radiation curable layer. In some embodiments, the flexographic printing plate precursor further comprises metal layer between the substrate and radiation curable layer, or both coversheet and metal layer sandwiching the radiation curable layer.

In some embodiments, the radiation curable layer can be a UV-sensitive layer that is cured by UV light. In some aspects, the UV-sensitive layer can be at least one layer of a relief-forming precursor that is formed by a relief-forming material that is UV-sensitive. Thus, references to the relief-forming material or layer refers to the UV-sensitive material or layer that can be irradiated with UV light and developed into a relief image.

In some embodiments, the relief-forming precursor includes: a backing or base film (e.g., as a substrate), a relief-forming layer (e.g., UV-sensitive material); and optionally a removable coversheet film to protect the photosensitive layer. In another option, a metal layer can be located between the substrate and the relief-forming layer.

In some embodiments, the backing or base can be configured to provide support to the relief-forming layer of the relief-forming precursor. The backing layer can be formed from transparent or opaque material such as paper, cellulose film, plastic, or metal. The backing layer is preferably formed from a transparent material that is flexible. Examples of such materials are cellulose films or plastics such as, PET (polyethylene terephthalate), PEN (polyethylene naphthalate), polyether, polyethylene, polyamide (Kevlar), or nylon. Preferably, the support layer is formed from polyethylene terephthalate (PET). It was also found that the relief-forming layer having the low surface energy additive was able to adhere to the support layer. The support layer can be from about 0.001 to about 0.010 inches thick. Optionally, various layers, such as an antihalation layer and/or an adhesive layer may be positioned between the backing layer and the relief-forming layer. In some aspects, the adhesive layer can include an antihalation material (e.g., light absorbing substance to prevent refraction of light) or may exclude such an antihalation material.

In some embodiments, the relief-forming layer can be a UV light photosensitive material that forms a relief image upon imaging with UV light and developing the image, where the relief image has reduced surface energy. Addition of a low surface energy additive to the UV light photosensitive material can provide a number of desirable properties to a relief image forming protocol, such as easier vacuum drawdown and better lamination to reduce bubble formation. Additionally, the reduced peel force allows for easier removal of the imaged mask from the relief-forming layer after the main UV exposure to form the relief image.

In some embodiments, a reduced surface energy and reduced peel force is obtained by incorporating a low surface energy additive into the composition of the photosensitive material. The low surface energy additive can be included within the matrix of the photosensitive material so as to be present and distributed within the body and on the surface of the photosensitive material. Often, the low surface energy additive is homogeneously mixed within the photosensitive material. However, the additive may be provided randomly or heterogeneously (e.g., non-homogeneously) or in gradients with increasing concentration preferentially to one side or the other.

In some embodiments, the low surface energy additive can include a silicone material, such as a silicone-based monomer having a reactive functional group. The reactive functional group can be selected to be polymerizable with the other polymerizable monomers of the photosensitive material. This allows the silicone to be incorporated into the polymerized material so that it is retained to the portion of the photosensitive material that remains after the relief forming process. As a result, the reactive functional group can be tailored from well-known functional groups that can participate in a polymerization reaction with specific types of other monomers that have the same functional groups or different but suitably reactive functional groups.

The low surface energy additive provides easer separation of the mask from the relief-forming precursor. It also provides a lower surface energy to the relief image layer of the flexographic printing plate which may provide additional benefit for printing.

In some embodiments, the relief-forming precursor can include only a single body or single layer of the UV-sensitive material. That is, the substrate of the relief-forming precursor can include only a single layer of the UV-sensitive material. As such, the UV-sensitive material is the top layer when ready to be combined with the mask to contact the particulate-treated protective topcoat, and the same UV-sensitive material is the only UV-sensitive material in the relief-forming precursor. A second UV-sensitive layer, whether adjacent or separate, is omitted from the relief-forming precursor described herein.

Some embodiments of relief-forming precursors can include a removable coversheet on the photosensitive layer.

In some embodiments, the photosensitive material can be a UV-sensitive layer that includes: an elastomeric binder; at least one polymerizable or photocurable monomer; a photopolymerizing photoinitiator that is sensitive to UV radiation; and a low surface energy monomer, such as the polymerizable silicone material described herein. Suitable photoinitiator compositions include but are not limited to those described in U.S. Pat. No. 4,323,637 (Chen et al.), U.S. Pat. No. 4,427,749 (Graetzel et al.), and U.S. Pat. No. 4,894,315 (Feinberg et al.). The low surface energy monomer can be added to the photoinitiator compositions to form the photosensitive material with reduced surface energy and reduced peel force.

The elastomeric binder can include more polymers or resins that can be soluble, swellable, or dispersible in aqueous, semi-aqueous, or organic solvent developers (described below) and can include but are not limited to, natural or synthetic polymers of conjugated diolefins, block copolymers, core-shell microgels, and blends of microgels and preformed macromolecular polymers. The elastomeric binder can comprise at least 65 weight % and up to and including 90 weight %, based on total dry UV-sensitive layer weight.

In some embodiments, the elastomeric binder may be a single polymer or mixture of polymers (e.g., homopolymers, copolymers, random copolymers, block copolymers, any with any number of different types of monomers) which may be soluble, swellable or dispersible in aqueous, semi-aqueous or organic solvent developers. Suitable binders include those described in, U.S. Pat. No. 3,458,311 (Alles), U.S. Pat. No. 4,442,302 (Pohl), U.S. Pat. No. 4,361,640 (Pine), U.S. Pat. No. 3,794,494 (Inoue), U.S. Pat. No. 4,177,074 (Proskow), U.S. Pat. No. 4,431,723 (Proskow), and U.S. Pat. No. 4,517,279 (Worns). Binders which are soluble, swellable or dispersible in organic solvent developers include natural or synthetic polymers of conjugated diolefin hydrocarbons, including polyisoprene, 1,2-polybutadiene, 1,4-polybutadiene, butadiene/acrylonitrile, butadiene/styrene thermoplastic-elastomeric block copolymers and other copolymers. The block copolymers discussed in U.S. Pat. No. 4,323,636 (Chen), U.S. Pat. No. 4,430,417 (Heinz), and U.S. Pat. No. 4,045,231 (Toda) may be used. The elastomeric binder may be present in an amount of at least about 65% by weight of the photosensitive material. The term binder, as used herein, encompasses core-shell microgels and blends of microgels and preformed macromolecular polymers, such as those described in U.S. Pat. No. 4,956,252 (Fryd).

The at least one polymerizable monomer can be configured to be compatible with the elastomeric binder to the extent that a clear, non-cloudy UV-sensitive imageable layer is produced. Polymerizable monomers for this purpose are well known the art and include ethylenically unsaturated polymerizable compounds having relatively low molecular weight (generally less than 30,000 Daltons). Suitable monomers have a relatively low molecular weight, less than about 5000 Da. Unless described otherwise, throughout the specification molecular weight is the weight-average molecular weight. Examples of suitable polymerizable monomers include various mono- and polyacrylates, acrylate derivatives of isocyanates, esters, and epoxides. Additionally, examples of suitable monomers include t-butyl acrylate, lauryl acrylate, the acrylate and methacrylate mono- and polyesters of alcohols and polyols such as alkanols, e.g., 1,4-butanediol diacrylate, 2,2,4-trimethyl-1,3 pentanediol dimethacrylate, and 2,2-dimethylolpropane diacrylate, alkylene glycols, e.g., tripropylene glycol diacrylate, butylene glycol dimethacrylate, hexamethylene glycol diacrylate, and hexamethylene glycol dimethacrylate, trimethylol propane, ethoxylated trimethylol propane, pentaerythritol, e.g., pentaerythritol triacrylate, dipentaerythritol, and the like. Other examples of suitable monomers include acrylate and methacrylate derivatives of isocyanates, esters, epoxides and the like, such as decamethylene glycol diacrylate, 2,2-di(p-hydroxyphenyl)propane diacrylate, 2,2-di(p-hydroxyphenyl)propane dimethacrylate, polyoxyethyl-2,2-di(p-hydroxyphenyl)propane dimethacrylate, and 1-phenyl ethylene-1,2-dimethacrylate. Further examples of monomers can be found in U.S. Pat. No. 4,323,636 (Chen), U.S. Pat. No. 4,753,865 (Fryd), U.S. Pat. No. 4,726,877 (Fryd), and U.S. Pat. No. 4,894,315 (Feinberg). The monomer may comprise at least 5% by weight to about 25% by weight of the photosensitive material, which can be based on total dry weight of the photosensitive material.

The photoinitiator may be any single compound or combination of compounds sensitive to ultraviolet radiation, generating free radicals which initiate the polymerization of the monomer or monomers without excessive termination. The photoinitiator can be sensitive to visible or ultraviolet radiation. The photoinitiator may also be insensitive to infrared and/or visible radiation and can be thermally inactive at and below 185° C. Examples of suitable photoinitiators include the substituted and unsubstituted polynuclear quinones. Examples of suitable systems have been disclosed in U.S. Pat. No. 4,460,675 (Gruetzmacher) and U.S. Pat. No. 4,894,315 (Feinberg). Photoinitiators are generally present in amounts from 0.001% to 10.0% by weight based on the weight of the photosensitive material.

In some embodiments, the photosensitive layer can include: a di- or tri-block co-polymer (e.g., elastomer); at least one photopolymerizable monomer; photopolymerization initiator; plasticizer; additives such as stabilizers, inhibitors, colorants, solvents; and the low surface energy monomer, such as, a silicone acrylate or silicone methacrylate.

In some embodiments, the plasticizer can be any suitable plasticizer known in the art of photosensitive layers for use as described herein. Examples of suitable plasticizers include aliphatic hydrocarbon oils, e.g., naphthenic and paraffinic oils, liquid polydienes, e.g., liquid polybutadiene, liquid polyisoprene. Generally, plasticizers are liquids having molecular weights of less than about 5,000 Da, but can have molecular weights up to about 30,000 Da. Plasticizers having low molecular weight will encompass molecular weights less than about 30,000 Da.

In some embodiments, the additives can include rheology modifiers, thermal polymerization inhibitors, stabilizers, inhibitors, tackifiers, colorants, antioxidants, antiozonants, solvents, or fillers. These materials are commonly used in photosensitive layers and examples can be provided in the incorporated references.

The thickness of the photosensitive layer may vary depending upon the type of printing plate desired. In one embodiment, the photosensitive layer may be, for example, from about 20-250 mils (500-6,400 microns) or greater in thickness, more particularly from about 20-100 mils (500-2,500 microns) in thickness.

In some embodiments, the relief-forming precursor is a flexographic printing plate precursor that includes a suitable UV-curable composition (e.g., photosensitive material) in the UV-sensitive layer (e.g., photosensitive layer) that when exposed through the mask element and developed, provides a relief image in a flexographic printing plate. Such relief-forming precursors generally include a suitable substrate with the photosensitive material. Examples of commercially available flexographic printing plate precursors include but are not limited to, FLEXCEL NX flexographic elements available from Miraclon Corporation, CYREL® Flexographic plates available from DuPont (Wilmington, Del.), NYLOFLEX® FAR 284 plates available from BASF (Germany), FLEXILIGHT CBU plate available from Macdermid (Denver, Co.), and ASAHI AFP XDI available from Asahi Kasei (Japan).

In some embodiments, the relief-forming precursor can also be used to form a printed circuit board wherein a conducting layer (also known as a “printing circuit”) is formed on a substrate in the pattern dictated by exposure through a mask element. Suitable precursors to printed circuit boards generally comprise a substrate, a metal layer, and a UV-sensitive imageable layer (e.g., photosensitive material). Suitable substrates include but are not limited to, polyimide films, glass-filled epoxy or phenol-formaldehyde or any other insulating materials known in the art. The metal layer covering the substrate is generally a conductive metal such as copper or an alloy or metals. The UV-sensitive imageable layer can include an UV-curable resin, polymerizable monomers, or oligomers, photoinitiators, and a polymeric binder. Further details of printed circuit boards are provided in U.S. '182 (noted above).

Forming Relief Images

After the mask element (e.g., with the particulate-treated protective topcoat) and relief-forming precursor are both formed as described above, the particulate-treated protective topcoat of the mask element is brought into complete optical contact with the relief-forming precursor that includes the photosensitive layer that is sensitive to curing UV radiation. This protocol can be accomplished by placing the particulate-treated protective topcoat of the mask element onto the relief-forming precursor or vice versa, as described below in more detail. For example, the contact and coupling of the particulate-treated protective topcoat of the mask element to the relief-forming precursor can be performed by using lamination equipment and processing. Vacuum drawdown of the particulate-treated protective topcoat of the mask element onto the relief-forming precursor can also be carried out, with or without lamination, to achieve desired complete optical contact.

Some embodiments according to the present invention can be understood by reference to the general illustrations provided in the sequence of FIG. 1A through FIG. 1E. As described above, FIG. 1A illustrates mask precursor 10 (or mask precursor 110 can be used) that is exposed to exposing infrared radiation 35 to form mask element 36 (FIG. 1B).

When the mask precursor 110 is used, the ablation may also ablate some of the barrier layer 120.

In FIG. 1C, mask element 36 includes the IL layer 15 over the LTHC layer 20 (or barrier layer 120) that is over the ablated IL layer 30 that has the mask image formed therein with the ablated particulate-treated protective topcoat 38 (or 138). The mask element 36 is shown in intimate or complete optical contact with a relief-forming precursor 55 to provide relief-image forming assembly 50 by contacting the particulate-treated protective topcoat 38 (or 138). Relief-forming precursor 55 includes the UV-sensitive layer 60 that is typically carried on substrate 65.

FIG. 1D shows the step of exposing the relief-image forming assembly 50 to UV radiation 70 shown by the arrows. The UV radiation 70 passes through the transparent polymeric carrier sheet 15, the LTHC layer 20 (or barrier layer 120), and the exposed regions (e.g., element 40—removed IL layer portions) of IL 30 in the mask element 36 and then the exposed portions in the particulate-treated protective topcoat 38 (or 138) to cause photocuring in UV-sensitive layer 60 of the relief-forming precursor 55.

After the UV-exposure, mask element 36 can be removed from the UV-sensitive layer 60 of the relief-forming precursor 55 and a development protocol can provide a relief image (FIG. 1E) in the UV-sensitive layer 60. As shown, the relief image includes relief image peaks 75 and relief image valleys 80 in the UV-sensitive layer 60.

It is noted that the particulate-treated protective topcoat 38 is peeled from the UV-sensitive layer 60. The particulates can improve the resolution and hilite retention of the resulting relief image shown in FIG. 1E.

Lamination

As noted above, the mask element and relief-forming precursor can be placed in complete optical contact so as to provide an air-free interface at the shared interface between the particulate-treated protective topcoat and UV-sensitive layer. Generally, this is achieved by laminating the mask element to the UV-sensitive layer of the relief-forming precursor by applying suitable pressure or heat, or both pressure and heat to form an air-free or gap-free interface prior to UV exposure. However, when the relief-forming precursor includes the UV-sensitive layer 60 having the low surface energy additive as described above, the laminating procedure may be not needed. As noted above, vacuum drawdown of the masking element onto the relief-forming precursor can then be useful.

Commercially available laminators that provide both heat and uniform pressure can be used including but not limited to, KODAK model 800XL APPROVAL LAMINATOR available from Eastman Kodak Company (Rochester, N.Y.). CODOR LPP650 LAMINATOR available from CODOR (Amsterdam, Holland), and LEDCO HD laminators available from Filmsource (Casselbury, Fla.) can also be useful.

In some embodiments, the particulate-treated protective topcoat can be removed before lamination or other operations of forming complete optical contact of mask element with the relief-forming precursor. The relief-image forming assembly formed by coupling the mask element and the relief-forming precursor can be fed into the laminator at a desired speed, temperature, and pressure.

Useful lamination (laminator) devices and methods for using them are described for example in U.S. Pat. No. 7,802,598 (Zwadlo et al.), the disclosure of which is incorporated herein by reference. As noted therein, a pre-press flexographic plate laminator can be used to laminate a mask element (“masking film”) on a relief-forming precursor (“pre-press flexographic printing plate”) by applying a balanced, non-distorting, optimized laminating force to achieve complete optical contact while minimizing lateral distortion.

In some embodiments, the relief-forming precursor does not have a separation layer, spacer layer, or anti-tack layer over the UV-sensitive relief-forming layer, and thereby pressure alone can be sufficient to achieve an air-free interface, as the relief-forming layer having the low surface energy additive within the relief-forming layer can still be tacky, or act as a pressure sensitive adhesive, due to the presence of polymerizable monomers. The amount of the low surface energy additive can be modulated within the parameters defined herein to obtain a desired or optimal amount of tackiness. Too much low surface energy monomer can cause a less tacky surface, and then hot lamination may be used to provide the optical contact coupling with the mask.

In some embodiments, the relief-forming precursor has a separation layer, spacer layer, or anti-tack layer over the UV-sensitive relief-forming layer.

UV Exposure

After complete optical contact has been achieved between the mask element and the relief-forming precursor as described above, the relief-forming precursor can be exposed to curing UV radiation through the mask element to form an imaged relief-forming precursor with exposed regions and non-exposed regions in the UV-sensitive layer. The exposed regions are cured and solidified by polymerization of the monomers in the UV-sensitive layer. The non-exposed regions remain uncured and the monomers are not polymerized. Thus, the uniformly emitted curing UV radiation is projected onto the relief-forming precursor through the mask image that preferentially blocks some of the ultraviolet radiation by the remaining portions of the IL layer. In unmasked (exposed) regions, the curing UV radiation will cause hardening or curing of the UV-sensitive composition(s) in the IL. The mask image is therefore substantially opaque to the exposing or curing UV radiation, meaning that the mask image should have a transmission optical density of 2 or more and typically 3 or more in the non-exposed regions. The remaining portion of the IL layer still include the UV sensitive material to absorb the UV light and block it. The unmasked (exposed) regions of the UV-sensitive composition can be substantially transparent meaning that they should have a transmission optical density of 0.5 or less, or even 0.1 or less, and more typically at least 0.5 and up to and including 0.1 or at least 0.1 and up to and including 0.3. Transmission optical density can be measured using a suitable filter on a densitometer, for example, a MACBETH TR 927 densitometer.

Generally, exposure of the relief-forming precursor through the mask element is accomplished by floodwise exposure from suitable irradiation sources of UV radiation. Exposure can be carried out in the presence of atmospheric oxygen. Exposure under vacuum is not necessary as complete optical contact has already been made.

In the manufacture of a relief imaging element, such as a flexographic printing plate, one side of the relief-forming precursor can be generally first exposed to curing UV radiation through its transparent substrate (known as “back exposure”) to prepare a thin, uniform cured layer (e.g., relief image valleys 80) on the substrate side of the UV-sensitive layer. The relief-forming precursor is then exposed to curing UV radiation through the mask element containing the mask image, thereby causing the UV-sensitive to harden or cure in the unmasked (exposed) regions. Unexposed and uncured regions of the UV-sensitive layer can then be removed by a developing process (described below), leaving the cured or hardened regions (e.g., relief image peaks 75) that define the relief image printing surface of a predetermined desired pattern of shapes and sizes of peaks 75 and valleys 80. The back exposure can be performed either before or after complete optical contact is made between the mask element and the relief-forming layer.

The wavelength or range of wavelengths suitable as the curing UV radiation will be dictated by the electromagnetic sensitivity of the relief-forming layer. In some embodiments, the UV curing radiation can have one or more wavelengths in the range of at least 150 nm and up to and including 450 nm, or more typically of at least 300 nm and up to and including 450 nm. Sources of UV radiation for floodwise or overall exposure include but are not limited to, carbon arcs, mercury-vapor arcs, fluorescent lamps, electron flash units, and photographic flood lamps. UV radiation is particularly useful from mercury-vapor lamps and sun lamps. Representative UV radiation sources include SYLVANIA 350 BLACKLIGHT fluorescent lamp (FR 48T12/350 VL/VHO/180, 115 watts) that has a central emission wavelength of about 354 nm that is available from Topbulb (East Chicago, Ind.), and BURGESS EXPOSURE FRAME, Model 5K-3343V511 with ADDALUX 754-18017 lamp available from Burgess Industries, Inc. (Plymouth, Mass.).

Other suitable sources of UV radiation include platemakers that can be used to both expose the relief-forming precursor to radiation and to develop the imaged relief-forming material after radiation exposure. Examples of suitable platemakers include but are not limited to, KELLEIGH MODEL 310 PLATEMAKER available from Kelleigh Corporation (Trenton, N.J.) and the GPP500F PLATE PROCESSOR available from Global Asia Ltd. (Hong Kong).

The time for exposure through the mask element will depend upon the nature and thickness of the UV-sensitive layer of the relief-forming precursor and the source of the and strength of the UV radiation. For example, in one of embodiment, a FLEXCEL-SRH plate precursor available from Eastman Kodak Company can be mounted on a KELLEIGH MODEL 310 PLATEMAKER and back exposed to UV-A radiation through the transparent support for about 20 seconds to prepare a thin, uniform cured layer on the support side of the relief-forming precursor. The relief image forming assembly of mask element and relief-forming precursor can then be exposed to UV radiation through the mask element for about 14 minutes. The mask image information is thus transferred to the relief-forming precursor (such as a flexographic plate precursor).

Separating Mask from UV-Sensitive Layer

In general, the methods described herein can also include removing the mask element from complete optical contact with the imaged relief-forming precursor after the UV exposure and before developing. Such removal can be by separating the particulate-treated protective topcoat from the relief image. This can be done using any suitable manner, such as peeling the two elements apart. For example, this can be accomplished by pulling the mask element away from the imaged relief-forming precursor.

In some embodiments, after the UV exposure, the mask element can be removed from the relief-forming layer by peeling the particulate-treated protective topcoat of the mask element from the relief-forming layer. This can be performed by providing support to one of the mask element or relief-forming precursor, and then applying a pulling force to an edge or end of the other of the mask element or relief-forming precursor (e.g., the relief-forming layer).

In some embodiments, the mask element can be delaminated from the relief-forming precursor, such as by being delaminated the particulate-treated protective topcoat from the relief-forming layer. In these embodiments, the mask element is laminated to the relief-forming layer. Then, the mask is delaminated from the relief-forming layer after the UV curing. However, such delamination is not intended to indicate that the mask itself delaminates so that the different layers of the mask element are delaminated from each other. Here, the mask element is delaminated in whole from the relief-forming layer. Thus, while the mask is delaminated from the relief-forming layer, the mask itself is not delaminated and damaged. Similarly, the relief-forming layer is not delaminated from the relief-forming precursor.

In some embodiments, the relief-forming precursor can include or omit a transparent release layer on the UV-sensitive layer. Thus, the UV-sensitive relief-forming layer can be in direct contact with the particulate-treated protective topcoat of the mask element, such that separation separates the mask directly from the relief-forming layer.

In some embodiments, the relief-forming layer can allow for less force to be applied during the peeling apart of the mask and the imaged relief-image precursor (e.g., flexographic printing plate precursor). The mask can be peeled away from the relief-forming precursor more quickly and completely, leaving little is no residual material. This effect provides more rapid development of the imaged relief-image precursor as there is little or no residual material to inhibit the development process. Because peeling is easier, minimal handling and hold down pressure is needed with the flexographic imaging assembly and the process can be readily carried out at room temperature. Thus, heating during the curing process may not be needed.

The flexographic printing plate assembly having the UV-sensitive layer includes a unique combination of materials so that peeling away of the mask can be quick and complete. By “complete”, at least 95% and preferably at least 98%, at least 99%, or 100% of the mask is peeled off, leaving very little or no residual material. The composition of the UV-sensitive layer provides a peel force in relation to a mask element comprising a mask image of less than about 73 g/inch, preferably less than about 60 g/inch, and more preferably less than about 55 g/in).

In some embodiments, the mask element containing the mask image is removed from the UV-exposed UV-sensitive relief-forming layer of the flexographic printing plate precursor by peeling it away at the interface of the mask element and relief-forming layer. This peeling process can be carried out as described in U.S. Pat. No. 7,802,598 using vacuum to hold in place. A corner of the mask element is then pulled away from the printing plate at a rate of 2 to 10 cm/sec at peel angle of 150-180° thereby essentially pulling the imaged film back on itself and keeping the imaged film near the vacuum table surface in a continuous motion until the entire mask element is removed from the UV-sensitive layer of the printing plate. In the practice of this invention, at least 95 weight % and preferably 100% of the dry mask element is removed in this operation, so that it can be generally said that the mask element is “completely” or substantially completely removed from the exposed radiation curable layer of the precursor. By “complete”, at least 95% and preferably at least 98%, at least 99%, or 100% of the mask is peeled off, leaving very little or no residual material.

Development

After the mask element is removed from the relief-forming layer, the imaged relief-forming precursor is then generally developed with a suitable developer (or processing solution, or “washout solution”) to form a relief image. Development serves to remove the non-exposed (uncured) regions of the UV-sensitive layer, leaving the exposed (cured) regions that define the relief image as shown in FIG. 1E.

Any known organic solvent-based or aqueous-based developer can be used in this processing step including known developers that contain predominantly chlorinated organic solvents. However, other useful developers are predominantly non-chlorinated organic solvents. By “predominantly,” it is meant that more than 50% (by volume) of the developer comprises one or more non-chlorinated organic solvents such as aliphatic hydrocarbons and long chain alcohols (that is alcohols with at least 7 carbon atoms). The remainder of the developers can be chlorinated organic solvents that are known in the art for this purpose.

Certain useful developers are predominantly what are known as “perchloroethylene alternative solvents” (PAS) that are generally volatile organic compounds typically comprised of mixtures of aliphatic hydrocarbons and long-chain alcohols. Examples of such commercially available solvents include but are not limited to, PLATESOLV available from Hydrite Chemical Co. (Brookfield, Wisc.), NYLOSOLV® available from BASF (Germany), FLEXOSOL® available from DuPont (Wilmington, Del.), OptiSol® available from DuPont (Wilmington, Del.), and SOLVIT° QD available from MacDermid (Denver, Co.).

Other useful developers are described in U.S. Pat. No. 5,354,645 (Schober et al.), the disclosure of which is incorporated herein by reference, and include one or more of diethylene glycol dialkyl ethers, acetic acid esters or alcohols, carboxylic acid esters, and esters of alkoxy substituted carboxylic acids. Still other useful developers are described in U.S. Pat. No. 6,162,593 (Wyatt et al) described developers comprising diisopropylbenzene (DIPB), and U.S. Pat. No. 6,248,502 (Eklund).

Additional useful developers are described in U.S. Pat. No. 6,582,886 (Hendrickson et al.) and contain methyl esters alone or mixtures of methyl esters and co-solvents such as various alcohols that are soluble in the methyl ester(s). U.S. Patent Application Publication 2010/0068651 (Bradford) describes useful developers containing dipropylene glycol dimethyl ether (DME) alone or in combination with various co-solvents such as alcohols and aliphatic dibasic acid ethers. Still other useful developers are described in U.S. Patent Application Publication 2011/0183260 (Fohrenkamm et al.). Other useful developers are described in U.S. Pat. No. 8,771,925 (Fohrenkamm et al.) which developer includes diisopropylbenzene and one or more organic co-solvents, one of which is an aliphatic dibasic acid ester. Still other useful developers are described in U.S. Pat. No. 9,005,884 (Yawata et al.) which processing solution can include an alkali metal salt of a saturated fatty acid having a carbon number of 12 to 18 and an alkali metal salt of an unsaturated fatty acid having a carbon number of 12 to 18 in a weight ratio of from 20:80 to 80:20 of the first fatty acid salt to the second fatty acid salt.

Still other useful developers are described in copending and commonly assigned U.S. Pat. No. 10,248,025 (Ollmann et al.). Such flexographic developers can comprise: a) a fatty acid composition consisting of one or more saturated or unsaturated fatty acids or alkali metal salts thereof, each saturated or unsaturated fatty acid or alkali metal salt thereof independently having 12 to 20 carbon atoms, the fatty acid composition being present in an amount of at least 0.25 weight % and up to and including 2.0 weight %, and at least 85 weight % of the fatty acid composition is composed of one or more C18 mono- or poly-unsaturated fatty acids or alkali metal salts thereof; b) an aminopolycarboxylic acid or alkali metal salt thereof in an amount of at least 0.05 weight % and up to and including 0.30 weight %; c) a buffer compound in an amount of at least 05 weight % and up to and including 0.60 weight %; and d) water.

Development can be carried out under known conditions such as for at least 1 minute and up to and including 20 minutes and at a temperature of at least 20° C. and up to and including 32° C. The type of developing apparatus and specific developer that are used will dictate the specific development conditions and can be adapted by a skilled worker in the art.

Post-development processing of the relief image in the imaged relief-forming precursor can be suitable under some circumstances. Typical post-development processing includes drying the relief image to remove any excess solvent and post-curing by exposing the relief image to curing radiation to cause further hardening or crosslinking. The conditions for these processes are well known to those skilled in the art. For example, the relief image can be blotted or wiped dry, or dried in a forced air or infrared oven. Drying times and temperatures would be apparent to a skilled artisan. Post-curing can be carried out using the same type of UV-radiation previously used to expose the relief-forming precursor through the imaged mask material.

Detackification (or “light finishing”) can be used if the relief image surface is still tacky. Such treatments, for example, by treatment with bromide or chlorine solutions or exposure to UV or visible radiation, are well known to a skilled artisan.

The resulting relief image can have a depth of at least 2% and up to and including 100% of the original thickness of the UV-sensitive layer (for example, if this layer is disposed on a substrate). For a flexographic printing plate, the maximum dry depth of the relief image can be from at least 150 μm and up to and including 1,000 μm, or typically at least 200 μm and up to and including 500 μm. For a printed circuit board, the UV-sensitive layer can be completely removed in either the exposed or non-exposed regions, to reveal the metal layer underneath. In such elements, the maximum depth of the relief image depends upon the dry thickness of the UV-sensitive layer. Advantageously, in any embodiment, the relief image can have shoulder angles of greater than 50°.

Thus, in some embodiments, the method is carried out where the relief-forming precursor is a UV-sensitive flexographic printing plate precursor and imaging and developing it such precursor to provide a flexographic printing plate that has a relief image layer formed from the relief-forming layer of the relief-forming precursor. Similarly, letterpress printing plates can be prepared from the appropriate precursor elements.

In some embodiments, the relief image layer can receive ink during the process of creating a relief image with the ink. The ink can be applied to the relief image layer in a suitable amount that helps the ink have printed dot-gain reduction. Accordingly, the relief image having the polymerized low surface energy moiety can facilitate reduction of the printed dot-gain. This overcomes an issue with flexographic printing plates having too high printed dot-gain. The particulate-treated protective topcoat can result in improved resolution and improve hilite retention of dots.

In some embodiments, the relief image layer having the ink can be cleaned to remove the ink for various reasons, such as changing color or cleaning the surface to apply new ink. Also, changing the ink can help remove any particles from the relief image layer that may be generated during the process. This provides for a clean relief surface so that the plate can be stored and then used again for printing.

One skilled in the art can readily see the various utilities that such inked elements would have in various industries including the flexographic printing of various packaging materials.

In some embodiments, the particulate-treated protective topcoat can be applied to Flexcel TIL-R to provide improved resolution to flexographic printing plates. Accordingly, a unique Thermal Imaging Film (TIF) formulation has been developed to improve resolution of flexographic plates made in the process known as Flexcel NX. By improving resolution, the particulate-treated protective topcoat of the mask can provide for improved hilite dot retention for a given amount of UV irradiation to prepare a flexographic NXH plate. It was found that the use of fine particles, such as a size (<1 microns) in the protective topcoat of the TIF improves hilite retention when used in flexographic plate making applications. The particles can be inorganic particles, such as silica particles, metal oxide particles, or others.

### EXAMPLES

An embodiment of the barrier layer was prepared as in the following table:

### Barrier Layer

| PCA solution | % Composition |
|---|---|
| Polycyanoacrylate | 6.811% |
| IR IRT | 0.115% |
| Adam Gates 670 | 0.274% |
| Cyclopentanone | 32.900% |
| Acetonitrile | 20.000% |
| Acetone | 39.700% |
| TOTAL: | 100% |

Polycyanoacrylate is from Eastman Kodak.
IR IRT is from Showa Denko.
Adam Gates 670 dye is from Adam Gates Co.
Cyclopentanone, Acetonitrile and Acetone are from Aldrich.

An embodiment of the IL was prepared as in the following table:

### IL

| UV Dye Solution | % Composition |
|---|---|
| Curcumin | 1.118% |
| Escalol 517 | 1.667% |
| Solvent Yellow 93 | 1.310% |
| Adam Gates 670 | 0.716% |
| Nitrocellulose E-150 | 40.10% (6%) |
| ADS 830 | 0.828% |
| EtOH | 4.856% |
| MEK | 3.400% |
| MIBK | 46.000% |
| TOTAL: | 100% |

Curcumin is available from Sigma Aldrich.
Escalol 517 is available from Ashland.
Solvent Yellow 93 is available from Epsilon Chemicals.
Adam Gates 670 dye is from Adam Gates Co.
Nitrocellulose E-150 is available from Nitroquimica Co.
ADS 830 is available form American Dye Source.
EtoH, MEK and MIBK are available from Sigma Aldrich.

A mask precursor was prepared on a PET substrate to include the barrier layer and

IL over the barrier layer. Onto 6.5 mil PET base (Mitsubishi 4747Z) the PCA Solution was coated (9bar 100 mg/ft2) with 2 minute drying (100 C). Onto the PCA coating the UV Dye solution was coated (17 bar 165 mg/ft2) with same drying as 1st layer. This was repeated to make 4 additional 2 layer coated sheets. These formulations were then coated each onto the previously coated samples (12 bar, 20 mg/ft², 2 min dry 100 C).

The following topcoat formulations were prepared:

| | Cond 1 | Cond 2 | Cond 3 | Cond 4 | Cond 5 |
|---|---|---|---|---|---|
| Aerodisp WK 7330 | 0 | 0.03 | 0.10 | 0.17 | 0.23 |
| Kolicoat MAE 30DP | 12.40 | 12.26 | 11.99 | 11.71 | 11.43 |
| (7%) | | | | | |
| Fluoro AQ-50 | 0.18 | 0.18 | 0.18 | 0.18 | 0.18 |
| Capstone FS-3100 | 0.01 | 0.01 | 0.01 | 0.01 | 0.01 |
| BYK 333 | 0.007 | 0.007 | 0.007 | 0.007 | 0.007 |
| Water | 87.40 | 87.35 | 87.56 | 87.78 | 88.0 |
| | 100 | 100 | 100 | 100 | 100 |
| % Aerodisp WK 7330 | 0% | 1% | 3% | 5% | 7% |
| in dry topcoat | | | | | |

Kolicoat MAE 30 DP is from BASF
Aerodisp WK 7330 is from Evonik (Particle Size 0.12 microns)
Fluoro AQ-50 is from Shamrock
Capstone FS-310 is from Dupont
BYK 333 is from BYK Co.

The masks prepared with the previous formulations, with the variations in amount of silica particles (e.g., Aerodisp WK 7330), were tested for imaging. These mask films were imaged on a Kodak Trendsetter were imaged at 145 DS to obtain Target Dmin values of 0.1-0.2.

NXH 114 plates were made using the Flexcel process. Back exposure was 19 sec and Main Exposure was 800 sec for the NXH plate exposures. Plates were then de-laminated and processed through the EVO processor using HPS CX solvent. Drying and post exposures were performed as normal NXH Flexcel process. Plate samples were evaluated using a 75× beta microscope and a Keyence microscope to evaluate RLD's (reverse line depths).

| Plate Feature | Cond 1 | Cond 2 | Cond 3 | Cond 4 | Cond 5 |
|---|---|---|---|---|---|
| 0.40% | 30-40% | 70-80% | 80-90% | 90% | 90% |
| 0.80% | F50% | 90% | 90% | 100% | 95% |
| RLD | 114 | 118 | 128 | 127 | 127 |
| Reliefs | 0.023 | 0.024 | 0.023 | 0.022 | 0.023 |

As can be seen from the data, the hilite retention of 0.4% dots and 0.8% dots was improved with increasing levels of the Aerodisp WK 7330. Improvement in hilite retention is seen with as little as 1% of the coated formulation. In addition RLD performance is improved with increased Aerodisp WK 7330. Plate Reliefs were in the same range for all plate samples.

An additional formulation was prepared in the same manner as above only this time the topcoat solution contained Aerodisp W 7512S (5.2% on dry formula). Aerodisp W7512S has a primary particle size of 0.10 microns, whereas Aerodisp WK 7330 has a primary particle size of 0.12 microns.

| Component | % composition |
|---|---|
| Aerodisp W 7512 S | 0.422% |
| Kolicoat MAE 30DP PM (NH4+) | 11.739% |
| Fluoro AQ-50 | 0.175% |
| Capstone FS-3100 | 0.097% |
| BYK 333 | 0.068% |
| Water | 87.50% |
| TOTAL | 100% |

NXH plates were made in the same manner as the previous example. Plate results were as follows:

| Plate Feature | Cond 4 |
|---|---|
| 0.40% | 85% |
| 0.80% | 100% |
| RLD | 127 |
| Reliefs | 0.023 |

These plate results show nearly the same response as with the Aerodisp WK 7330 (fumed silica and fumed mixed oxide) and much improved over those without any of the Aerodisp W 7512S (dispersion of fumed silica). Therefore, the use of particles, such as inorganic particles (e.g., non-ablatable silica particles) in the protective topcoat provides a significant improvement.

Summary

The data shows that by inclusion of inorganic particles (e.g., about 0.1 micron), such as colloidal silica, metal oxide, whether ablatable or not ablatable (e.g., silica), into the topcoat formulation improved imaging plate response compared to conditions without inclusion of the inorganic particles. Improvements are seen with as little as 1% of particles in the dry protective topcoat composition based on the dried topcoat formula. Without being bound to a particular theory, it is thought that these colloidal particles inhibit dyes from migrating from the TIF film into the NXH plate material. Such a migration of dyes from the TIF film to the NXH plate material causes loss of imaging resolution, which is avoided by particulate-treated protective topcoat. It is possible that these silica/metal oxide particles have strong affinity/absorptive characteristics for the dye materials and improve the topcoat barrier properties.

Definitions

As used herein to define various components of the non-ablatable light-to-heat converting (LTHC) layer, non-silver halide thermally-ablatable imaging layer (IL), and other materials, layers, and compositions (for example, a developer or processing solution) used in the practice of this invention, unless otherwise indicated, the singular forms “a,” “an,” and “the” are intended to include one or more of the components (that is, including plurality referents).

Each term that is not explicitly defined in the present application is to be understood to have a meaning that is commonly accepted by those skilled in the art. If the construction of a term would render it meaningless or essentially meaningless in its context, the term should be interpreted to have a standard dictionary meaning.

The use of numerical values in the various ranges specified herein, unless otherwise expressly indicated otherwise, are considered to be approximations as though the minimum and maximum values within the stated ranges were both preceded by the word “about.” In this manner, slight variations above and below the stated ranges may be useful to achieve substantially the same results as the values within the ranges. In addition, the disclosure of these ranges is intended as a continuous range including every value between the minimum and maximum values as well as the end points of the ranges.

The non-ablatable light-to-heat converting layer is also identified herein as the LTHC layer.

The non-silver halide thermally-ablatable imaging layer is also identified herein as the IL.

Unless indicated herein, the term “imageable material” is used to refer to embodiment articles prepared and used according to the present invention. Such imageable materials can also be known as “mask films,” “mask precursors,” or “masking elements.” The imageable material can be transformed into a “mask element” with suitable thermal (IR) imaging, which mask element contains a mask image that can be used to form a relief image according to the present invention.

Unless otherwise indicated, percentages are by weight.

The term “relief-forming precursor” used herein refers to any imageable element or imageable material in which a relief image can be produced by exposure through a mask element. Examples of such relief-forming precursors are described in detail below but some relief-forming precursors include flexographic printing plate precursors, letterpress printing plate precursors, and printed circuit boards. Details of useful relief-forming materials are described in U.S. Patent Application Publication 2005/0227182 (noted above), the disclosure of which is incorporated herein by reference. In this publication, the relief-forming precursors are generally identified as “radiation-sensitive elements.”

Unless otherwise indicated, the term “ablative” or “ablation” refers to thermal imaging by means of a laser that causes rapid local changes in the non-silver halide thermally-ablatable imaging layer (IL) of an imageable material thereby causing the material(s) in the IL to be ejected from the IL. This is distinguishable from other material transfer or imaging techniques such as melting, evaporation, or sublimation.

The terms “optical contact” and “complete optical contact” have the same meaning and refer to two layers or two elements (as in the case of the mask element and a relief-forming precursor) sharing an interface and being in intimate physical contact so that there is essentially no air-gap or void between the contacting surfaces, thus providing an “air-free interface.” More precisely, two surfaces are defined as being in optical contact when the reflection and transmission characteristics of their interface are essentially fully described by the Fresnel laws for the reflection and transmission of light at the refractive-index boundary.

Unless otherwise noted, the term “transparent” used herein refers to the ability of a material or layer to transmit at least 95% of impacting (or incident) electromagnetic radiation, such as electromagnetic radiation having a wavelength of at least 200 nm to and including 750 nm (that is, what are generally known in the art as UV and visible radiation). The transparent polymeric carrier sheet and LTHC layer described below particularly have this property.

“Average dry thickness” of a given dry layer is generally an average of 10 different measurements of a dry cross-sectional image of that layer.

One skilled in the art will appreciate that, for the processes and methods disclosed herein, the functions performed in the processes and methods may be implemented in differing order. Furthermore, the outlined steps and operations are only provided as examples, and some of the steps and operations may be optional, combined into fewer steps and operations, or expanded into additional steps and operations without detracting from the essence of the disclosed embodiments.

The present disclosure is not to be limited in terms of the particular embodiments described in this application, which are intended as illustrations of various aspects. Many modifications and variations can be made without departing from its spirit and scope, as will be apparent to those skilled in the art. Functionally equivalent methods and apparatuses within the scope of the disclosure, in addition to those enumerated herein, will be apparent to those skilled in the art from the foregoing descriptions. Such modifications and variations are intended to fall within the scope of the appended claims. The present disclosure is to be limited only by the terms of the appended claims, along with the full scope of equivalents to which such claims are entitled. It is to be understood that this disclosure is not limited to particular methods, reagents, compounds compositions or biological systems, which can, of course, vary. It is also to be understood that the terminology used herein is for the purpose of describing particular embodiments only, and is not intended to be limiting.

With respect to the use of substantially any plural and/or singular terms herein, those having skill in the art can translate from the plural to the singular and/or from the singular to the plural as is appropriate to the context and/or application. The various singular/plural permutations may be expressly set forth herein for sake of clarity.

It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to embodiments containing only one such recitation, even when the same claim includes the introductory phrases “one or more” or “at least one” and indefinite articles such as “a” or “an” (e.g., “a” and/or “an” should be interpreted to mean “at least one” or “one or more”); the same holds true for the use of definite articles used to introduce claim recitations. In addition, even if a specific number of an introduced claim recitation is explicitly recited, those skilled in the art will recognize that such recitation should be interpreted to mean at least the recited number (e.g., the bare recitation of “two recitations,” without other modifiers, means at least two recitations, or two or more recitations). Furthermore, in those instances where a convention analogous to “at least one of A, B, and C, etc.” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, etc.). In those instances where a convention analogous to “at least one of A, B, or C, etc.” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, etc.). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

In addition, where features or aspects of the disclosure are described in terms of Markush groups, those skilled in the art will recognize that the disclosure is also thereby described in terms of any individual member or subgroup of members of the Markush group.

As will be understood by one skilled in the art, for any and all purposes, such as in terms of providing a written description, all ranges disclosed herein also encompass any and all possible subranges and combinations of subranges thereof. Any listed range can be easily recognized as sufficiently describing and enabling the same range being broken down into at least equal halves, thirds, quarters, fifths, tenths, etc. As a non-limiting example, each range discussed herein can be readily broken down into a lower third, middle third and upper third, etc. As will also be understood by one skilled in the art all language such as “up to,” “at least,” and the like include the number recited and refer to ranges which can be subsequently broken down into subranges as discussed above. Finally, as will be understood by one skilled in the art, a range includes each individual member. Thus, for example, a group having 1-3 cells refers to groups having 1, 2, or 3 cells. Similarly, a group having 1-5 cells refers to groups having 1, 2, 3, 4, or 5 cells, and so forth.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

All references recited herein are incorporated herein by specific reference in their entirety.

1. A mask element for flexographic printing, the mask comprising:
a substrate;
a polymeric layer on the substrate and having at least one first infrared absorbing material;
a non-silver halide thermally-ablatable imaging layer on the polymeric layer and having at least one second infrared absorbing material and an ultraviolet absorbing material in an thermally-ablatable polymeric binder; and
a particulate-treated protective topcoat on the non-silver halide thermally-ablatable imaging layer and having a thermally-ablatable polymer containing inorganic particles of from about 0.25% to about 20% by dry weight of the particulate-treated protective topcoat.

2. The mask element of claim 1, wherein:
the polymeric layer includes a crosslinked polymer having particles that are not thermally-ablatable;
the non-silver halide thermally-ablatable imaging layer includes a non-crosslinked polymer; and
the particulate-treated protective topcoat includes a non-crosslinked polymer.

3. The mask element of claim 1, wherein:
the polymeric layer includes a non-crosslinked polymer;
the non-silver halide thermally-ablatable imaging layer includes a non-crosslinked polymer; and
the particulate-treated protective topcoat includes a non-crosslinked polymer.

4. The mask element of claim 1, wherein the inorganic particles include silicon dioxide or metal dioxide.

5. The mask element of claim 1, wherein the inorganic particles are a thermally-ablatable particles.

6. The mask element of claim 1, wherein the inorganic particles are not thermally ablatable particles.

7. The mask element of claim 1, wherein the inorganic particles are present from about 0.5% to 10%.

8. The mask element of claim 1, wherein the inorganic particles have a size range from 0.05 microns to 1 micron.

9. The mask element of claim 1, wherein at least one of:
the substrate includes polyethylene terephthalate;
the polymeric layer includes polycayanoacrylate;
the non-silver halide thermally-ablatable imaging layer includes nitrocellulose; or
the particulate-treated protective topcoat includes methacrylic acid-acrylate copolymer.

10. The mask element of claim 1, wherein the non-silver halide thermally-ablatable imaging layer has a mask image formed therein, wherein the mask image includes regions of the non-silver halide thermally-ablatable imaging layer and regions omitting the non-silver halide thermally-ablatable imaging layer that have been thermally ablated, wherein the particulate-treated protective topcoat includes regions over the regions of the non-silver halide thermally-ablatable imaging layer and omits regions over the regions omitting the non-silver halide thermally-ablatable imaging layer that have been thermally ablated.

11. A relief-forming assembly comprising:
a relief-forming precursor; and
a mask element for flexographic printing, the mask comprising:
a substrate;
a polymeric layer on the substrate and having at least one first infrared absorbing material;
a non-silver halide thermally-ablatable imaging layer on the polymeric layer and having at least one second infrared absorbing material and an ultraviolet absorbing material in an thermally-ablatable ablatable polymeric binder; and
a particulate-treated protective topcoat on the non-silver halide thermally-ablatable imaging layer and having a thermally-ablatable polymer containing inorganic particles of from about 0.25% to about 20% by dry weight of the particulate-treated protective topcoat,
wherein the non-silver halide thermally-ablatable imaging layer has a mask image formed therein, wherein the mask image includes regions of the non-silver halide thermally-ablatable imaging layer and regions that omit the non-silver halide thermally-ablatable imaging layer that have been thermally ablated,
wherein the particulate-treated protective topcoat includes regions over the regions of the non-silver halide thermally-ablatable imaging layer and omits regions over the regions omitting the non-silver halide thermally-ablatable imaging layer that have been thermally ablated.

12. The relief-forming assembly of claim 11, wherein the relief-forming precursor includes:
a substrate; and
a relief-forming layer having a bottom surface facing the substrate and a relief-forming surface facing away from the substrate, the relief-forming layer comprising:
a polymer;
at least one photopolymerizable monomer; and
a photopolymerization initiator.

13. A method of making the relief-forming assembly of claim 11, comprising:
placing the particulate-treated protective topcoat of the mask element on the relief-forming surface of the relief-forming layer; and
forming the complete optical contact between the mask element and the relief-forming surface.

14. The method of claim 11, further comprising at least one of:
laminating the mask element to the relief-forming surface; or
vacuum drawdown coupling the mask element to the relief-forming surface.

15. A method of making a relief image in a relief-forming assembly, the method comprising:
providing the relief-forming assembly of claim 11;
exposing a relief-forming layer of the relief-forming precursor to curing UV radiation through the mask element to form an imaged relief-forming layer with UV-exposed regions forming polymerized regions and non-exposed regions forming non-polymerized regions in the imaged relief-forming layer;
removing the mask element from the imaged relief-forming layer; and
developing the imaged relief-forming layer by removing the non-polymerized regions in the imaged relief-forming layer, thereby forming a relief image element having a relief image.

16. A method of making a mask element for flexographic printing, the method comprising:
providing a substrate;
forming a polymeric layer on the substrate, wherein the polymeric layer has at least one first infrared absorbing material;
forming a non-silver halide thermally-ablatable imaging layer on the polymeric layer, wherein the non-silver halide thermally-ablatable imaging layer has at least one second infrared absorbing material and an ultraviolet absorbing material in an thermally-ablatable polymeric binder; and
forming a particulate-treated protective topcoat on the non-silver halide thermally-ablatable imaging layer, wherein the particulate-treated protective topcoat has a thermally-ablatable polymer containing inorganic particles of from about 0.25% to about 20% by dry weight of the particulate-treated protective topcoat.

17. The method of claim 16, further comprising:
forming the polymeric layer with a crosslinked polymer to form a cross-linked matrix containing particles that are not thermally-ablatable;
forming the non-silver halide thermally-ablatable imaging layer to include a non-crosslinked polymer; and
forming the particulate-treated protective topcoat to include a non-crosslinked polymer.

18. The method of claim 16, further comprising:
forming the polymeric layer to include a non-crosslinked polymer;
forming the non-silver halide thermally-ablatable imaging layer to include a non-crosslinked polymer; and
forming the particulate-treated protective topcoat to include a non-crosslinked polymer.

19. The method of claim 16, wherein the inorganic particles include silicon dioxide or metal dioxide.

20. The method of claim 16, wherein the inorganic particles are present from about 0.5% to 10%.

21. The method of claim 16, wherein the inorganic particles have a size range from 0.05 microns to 1 micron.

22. The method of claim 16, further comprising exposing the particulate-treated protective topcoat and non-silver halide thermally-ablatable imaging layer to infrared radiation to selectively ablate regions in the particulate-treated protective topcoat and non-silver halide and non-silver halide thermally-ablatable imaging layer,
wherein the non-silver halide thermally-ablatable imaging layer has a mask image formed therein, wherein the mask image includes regions of the non-silver halide thermally-ablatable imaging layer and regions omitting the non-silver halide thermally-ablatable imaging layer that have been thermally ablated, wherein the particulate-treated protective topcoat includes regions over the regions of the non-silver halide thermally-ablatable imaging layer and omits regions over the regions omitting the non-silver halide thermally-ablatable imaging layer that have been thermally ablated.
